(19) United States
(12) Patent Application Publication
(10) Pub. No.: US 2008/0012097 A1
(43) Pub. Date: Jan. 17, 2008

(54) SEMICONDUCTOR DEVICE AND WIRELESS DEVICE USING THE SEMICONDUCTOR DEVICE

(75) Inventors: Hisashi Takahashi, Osaka (JP); Junji Ito, Osaka (JP); Hiroki Kojima, Shiga (JP)

Correspondence Address: RATNERPRESTIA, P.O. BOX 980, VALLEY FORGE, PA, 19482, US

(73) Assignee: MATSUSHITA ELECTRIC INDUSTRIAL CO., LTD., Osaka (JP)

(21) Appl. No.: 11/774,800

(22) Filed: Jul. 9, 2007

(30) Foreign Application Priority Data
Jul. 12, 2006 (JP) 2006-191680

(51) Int. Cl. H01L 23/552

(52) U.S. Cl. 257/659; 257/E23.114

(57) ABSTRACT

A semiconductor device has a semiconductor substrate; a shielding element formed by a conductor on a top side of the semiconductor substrate; an active element formed by a conductor and a semiconductor on the top side of the semiconductor substrate; a dielectric layer formed between the shielding element and the active element to electrically isolate the shielding element and the active element. The shielding element includes a first conductor layer formed as a flat plate, and a first external contact that is formed on the top side of the first conductor layer and is connected to the first conductor layer; and the active element includes a second conductor layer that is formed between the semiconductor substrate and the first conductor layer, and is connected to the semiconductor substrate.

### BACKGROUND OF THE INVENTION

1. Field of Invention

The present invention relates to technology for reducing the effects of a wireless circuit board when the semiconductor device is mounted on the wireless circuit board, and relates more particularly to technology for the semiconductor device and the wireless circuit board.

2. Description of Related Art

As cell phones and other wireless devices have become smaller, it has also been necessary to reduce the size of the semiconductor devices that are used in the wireless devices.

This has led to a semiconductor device packaging technology called wafer level chip size packaging (“WLCSP” below) that results in substantially the same external package dimensions as the semiconductor chip being used for the semiconductor devices used in wireless devices.

A WLCSP connects a copper or other conductor to the signal lines on a semiconductor substrate through an intervening insulation layer, post-shaped external contacts are formed on the copper conductor, and the copper conductor is coated with resin so that only the contacts are exposed.

U.S. Patent Application Publication No. 2002/0017730 (corresponding to Japanese Laid-open Patent Publication No. 2002-057292) teaches a WLCSP semiconductor device that has an inductor rendered in the conductor layer on the semiconductor substrate for connection to other circuits rendered on the semiconductor substrate.

Japanese Laid-open Patent Publication No. 2005-005741 teaches an arrangement for protecting circuits on the semiconductor substrate from the effects of noise from conductors on the semiconductor substrate.

When the WLCSP semiconductor device having an inductor rendered in the conductor layer on the semiconductor substrate as taught in U.S. Patent Application Publication No. 2002/0017730 is mounted on the circuit board of a wireless device, however, the parasitic capacitance around the inductor in the conductor layer differs before and after the device is mounted, the coupling capacitance to the inductor changes, and the inductance thus changes.

FIG. 19A is a plan view of a semiconductor device 100p according to the related art. This semiconductor device 100p has a semiconductor substrate 101p, a plurality of external contacts 102p, and a plurality of conductors 103p. FIG. 19B is a section view through line A1-A1 in FIG. 19A. Pads 104p that are connected to internal circuit 105p, and inductors for connection through a dielectric layer 106p to the conductors 103p, are rendered on the semiconductor substrate 101p, external contacts 102p are formed on the conductors 103p, and the conductors 103p are then covered with a sealing layer 107p. The resulting semiconductor device 100p with exposed contacts 102p is then connected to the contacts 108p of the wireless device 109p using the bumps 102p.

When a voltage-controlled oscillator is formed using a resonator including an inductor rendered in the conductors 103p and is mounted to the wireless device 109p as a WLCSP semiconductor device, the parasitic capacitance of the top inductor layer of the conductors 103p changes compared with before packaging with the wireless device. The coupling capacitance to the inductor and the inductance thus change, and the output frequency of the voltage-controlled oscillator will differ between when the semiconductor device is tested and when the semiconductor device is mounted to the wireless device.

An external device is commonly mounted to a contact of the semiconductor device in order to eliminate noise from the power supply. When the chip size becomes very small, however, circuit elements on the semiconductor chip can also be affected by noise directly from the printed wiring board on which the device is mounted, and not only from the external contacts. As shown in FIG. 19C, a filter with an inductor serially connected to the power supply prevents the transmission of low frequency noise that is superimposed on the supply voltage Vcc. In a PLL, which typically is easily affected by power supply noise, for example, superimposed sneak current noise from the power supply appears as phase noise in the oscillator. Low frequency power supply noise from the power source in particular is generally a problem because it cannot be suppressed by the loop filter of the PLL and is therefore contained in the PLL output.

As shown in FIG. 19D, a matching circuit is usually needed at the high frequency signal input/output nodes to reduce signal loss by a filter that has an inductance serially coupled to the input node. These components are required at all input/output nodes, and therefore increase the required mounting area in a multiband wireless communication device. The foregoing power supply noise elimination filter also increases the required mounting area when used with modern semiconductor IC chips with many pins. Embedding the inductor in the semiconductor chip is also conceivable, but this again increases the chip size and contributes to interference problems.

The present invention is directed to solving the foregoing problems by reducing the effect on a WLCSP semiconductor device when mounted in a wireless device.

### SUMMARY OF THE INVENTION

A first aspect of the invention is a semiconductor device having a semiconductor substrate; a shielding element formed by a conductor on a top side of the semiconductor substrate; an active element formed by a conductor and a semiconductor on the top side of the semiconductor substrate; a dielectric layer formed between the shielding element and the active element to electrically isolate the shielding element and the active element. The shielding element includes a first conductor layer formed as a flat plate, and a first external contact that is formed on the top side of the first conductor layer and is connected to the first conductor layer; and the active element includes a second conductor layer that is formed between the semiconductor substrate and the first conductor layer, and is connected to the semiconductor substrate.

A wireless device according to the present invention has a semiconductor device including a semiconductor substrate; a shielding element formed by a conductor on a top side of the semiconductor substrate; an active element formed by a conductor and a semiconductor on the top side of the semiconductor substrate; a dielectric layer formed between the shielding element and the active element to electrically isolate the shielding element and the active element. The shielding element includes a first conductor layer formed as a flat plate, and a first external contact that is formed on the top side of the first conductor layer and is connected to the first conductor layer; and the active element includes a second conductor layer that is formed between the semiconductor substrate and the first conductor layer, and is connected to the semiconductor substrate. The wireless device also has a third conductor layer that is formed in an area greater than the first conductor layer on the top side of the first external contact, and is connected to the first external contact; and a wiring board to which the third conductor layer is attached.

The flat plate-shaped conductor layer on the top layer of the semiconductor substrate in this semiconductor device shields the elements located below this plate-shaped conductor layer and thus reduces the effects of mounting on a wireless circuit board.

Other objects and attainments together with a fuller understanding of the invention will become apparent and appreciated by referring to the following description and claims taken in conjunction with the accompanying drawings.

### BRIEF DESCRIPTION OF THE DRAWINGS

FIG. 1A is a plan view of a semiconductor device according to a first embodiment of the invention.

FIG. 1B is a section view of a semiconductor device according to a first embodiment of the invention.

FIG. 2A is a plan view of a semiconductor device according to a second embodiment of the invention.

FIG. 2B is a section view of a semiconductor device according to a second embodiment of the invention.

FIG. 3A is a plan view of a semiconductor device according to a third embodiment of the invention.

FIG. 3B is a section view of a semiconductor device according to a third embodiment of the invention.

FIG. 4A is a plan view of a semiconductor device according to a fourth embodiment of the invention.

FIG. 4B is a section view of a semiconductor device according to a fourth embodiment of the invention.

FIG. 5A is a plan view of a semiconductor device according to a fifth embodiment of the invention.

FIG. 5B is a section view of a semiconductor device according to a fifth embodiment of the invention.

FIG. 6A is a plan view of a semiconductor device according to a sixth embodiment of the invention.

FIG. 6B is a section view of a semiconductor device according to a sixth embodiment of the invention.

FIG. 6C is a section view of a semiconductor device according to a sixth embodiment of the invention.

FIG. 7A is a plan view of a semiconductor device according to a seventh embodiment of the invention.

FIG. 7B is a section view of a semiconductor device according to a seventh embodiment of the invention.

FIG. 7C is a section view of a semiconductor device according to a seventh embodiment of the invention.

FIG. 8A is a plan view of a semiconductor device according to an eighth embodiment of the invention.

FIG. 8B is a section view of a semiconductor device according to an eighth embodiment of the invention.

FIG. 8C is a section view of a semiconductor device according to an eighth embodiment of the invention.

FIG. 9A is a plan view of a semiconductor device according to a ninth embodiment of the invention.

FIG. 9B is a plan view of a semiconductor device according to a ninth embodiment of the invention.

FIG. 9C is a section view of a semiconductor device according to a ninth embodiment of the invention.

FIG. 9D is a plan view of a semiconductor device according to a ninth embodiment of the invention.

FIG. 9E is a section view of a semiconductor device according to a ninth embodiment of the invention.

FIG. 9F is a plan view of a semiconductor device according to a ninth embodiment of the invention.

FIG. 9G is a section view of a semiconductor device according to a ninth embodiment of the invention.

FIG. 9H is a plan view of a semiconductor device according to a ninth embodiment of the invention.

FIG. 9I is a section view of a semiconductor device according to a ninth embodiment of the invention.

FIG. 9J is a plan view of a semiconductor device according to a ninth embodiment of the invention.

FIG. 9K is a section view of a semiconductor device according to a ninth embodiment of the invention.

FIG. 9L is a plan view of a semiconductor device according to a ninth embodiment of the invention.

FIG. 9M is a section view of a semiconductor device according to a ninth embodiment of the invention.

FIG. 9N is a section view of a semiconductor device according to a ninth embodiment of the invention.

FIG. 10A is a plan view of a semiconductor device according to a tenth embodiment of the invention.

FIG. 10B is a section view of a semiconductor device according to a tenth embodiment of the invention.

FIG. 11A is a plan view of a semiconductor device according to an eleventh embodiment of the invention.

FIG. 11B is a section view of a semiconductor device according to an eleventh embodiment of the invention.

FIG. 11C is a circuit diagram of a semiconductor device according to an eleventh embodiment of the invention.

FIG. 11D is a circuit diagram of a semiconductor device according to an eleventh embodiment of the invention.

FIG. 12A is a plan view of a semiconductor device according to a twelfth embodiment of the invention.

FIG. 12B is a section view of a semiconductor device according to a twelfth embodiment of the invention.

FIG. 12C is a plan view of a semiconductor device according to a twelfth embodiment of the invention.

FIG. 13A is a plan view of a semiconductor device according to a thirteenth embodiment of the invention.

FIG. 13B is a section view of a semiconductor device according to a thirteenth embodiment of the invention.

FIG. 13C is a plan view of a semiconductor device according to a thirteenth embodiment of the invention.

FIG. 14A is a plan view of a semiconductor device according to a fourteenth embodiment of the invention.

FIG. 14B is a section view of a semiconductor device according to a fourteenth embodiment of the invention.

FIG. 15A is a plan view of a semiconductor device according to a fifteenth embodiment of the invention.

FIG. 15B is a section view of a semiconductor device according to a fifteenth embodiment of the invention.

FIG. 16A is a plan view of a semiconductor device according to a sixteenth embodiment of the invention.

FIG. 16B is a section view of a semiconductor device according to a sixteenth embodiment of the invention.

FIG. 17 is a plan view of a semiconductor device according to a seventeenth embodiment of the invention.

FIG. 18A is a plan view of a semiconductor device according to an eighteenth embodiment of the invention.

FIG. 18B is a section view of a semiconductor device according to an eighteenth embodiment of the invention.

FIG. 19A is a plan view of a semiconductor device according to the related art.

FIG. 19B is a section view of a semiconductor device according to the related art.

FIG. 19C is a circuit diagram of a semiconductor device according to the related art.

FIG. 19D is a circuit diagram of a semiconductor device according to the related art.

### DETAILED DESCRIPTION OF THE PREFERRED EMBODIMENTS

Preferred embodiments of the present invention are described below with reference to the accompanying figures wherein elements of practically the same arrangement, operation, and effect are identified by like reference numerals. The values cited below are also by way of example only for describing specific embodiments of the invention, and the invention is not limited to these values.

### Embodiment 1

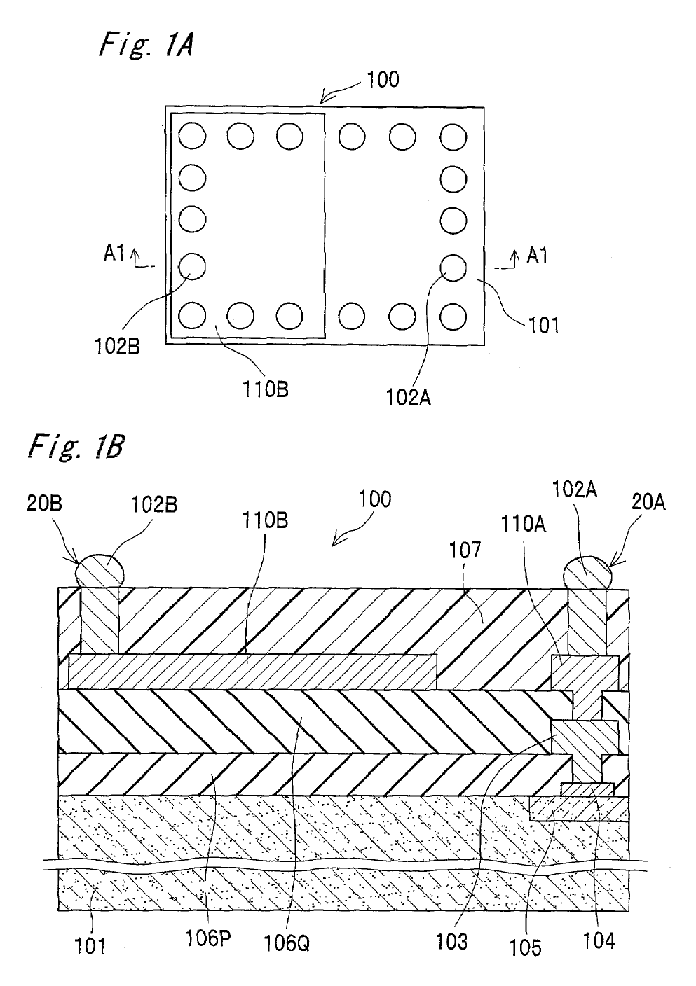

FIG. 1A is a plan view of a semiconductor 100 device according to a first embodiment of the invention, and FIG. 1B is a section view through line A1-A1 in FIG. 1A. A sealing layer 107 is also disposed to the semiconductor device 100 shown in FIG. 1A. The sealing layer 107 side of the semiconductor device 100 shown on the top in FIG. 1B is referred to as the top, and the semiconductor substrate 101 side shown on the bottom in FIG. 1B is referred to as the bottom.

The internal circuit 105 is formed on a semiconductor substrate 101 made of a semiconductor material. The pads 104 are made of aluminum, and are connected on one side to the internal circuit 105 and on the other side through a conductor layer 103 to the top conductor layer 110A. The first conductor layer 103 and the top conductor layer 110A are copper. The top conductor layer 110A is further connected to external contacts 102A formed on the top. The pads 104, the conductor layer 103, and the top conductor layer 110A pass through dielectric layers 106P and 106Q. A top conductor layer 110B rendered as a flat plate covers the semiconductor substrate 101 and is connected to at least one external contact 102B. The semiconductor device 100 is covered by the sealing layer 107 while leaving a part of external contacts 102A and 102B exposed.

The internal circuit 105, the pads 104, the conductor layer 103, the top conductor layer 110A, and the external contacts 102A render an active element 20A. The top conductor layer 110B and at least one external contact 102B render a shielding element 20B. The semiconductor device 100 includes the dielectric layers 106P and 106Q, the active element 20A, and the shielding element 20B. The shielding element 20B is physically separated and electrically isolated from the active element 20A by the dielectric layers 106P and 106Q.

By rendering the top conductor layer 110B as a flat plate, this embodiment of the invention electrostatically isolates the lower conductor layer 103 and internal circuit 105 from the top layer. As a result, the parasitic coupling capacitance between the conductor layer 103 and the internal circuit 105 and the printed wiring board of the wireless device disposed above the top conductor layer 110B by way of the intervening external contacts 102A and 102B can be greatly reduced. Resonance frequency variations and other adverse effects on the conductor layer 103 and the internal circuit 105 from the wiring board on which the semiconductor device 100 is mounted can therefore be eliminated.

### Embodiment 2

Primarily the differences between this second embodiment of the invention and the foregoing first embodiment are described below. Other aspects of the arrangement, operation and effect of this embodiment of the invention are the same as in the first embodiment, and further description thereof is thus omitted.

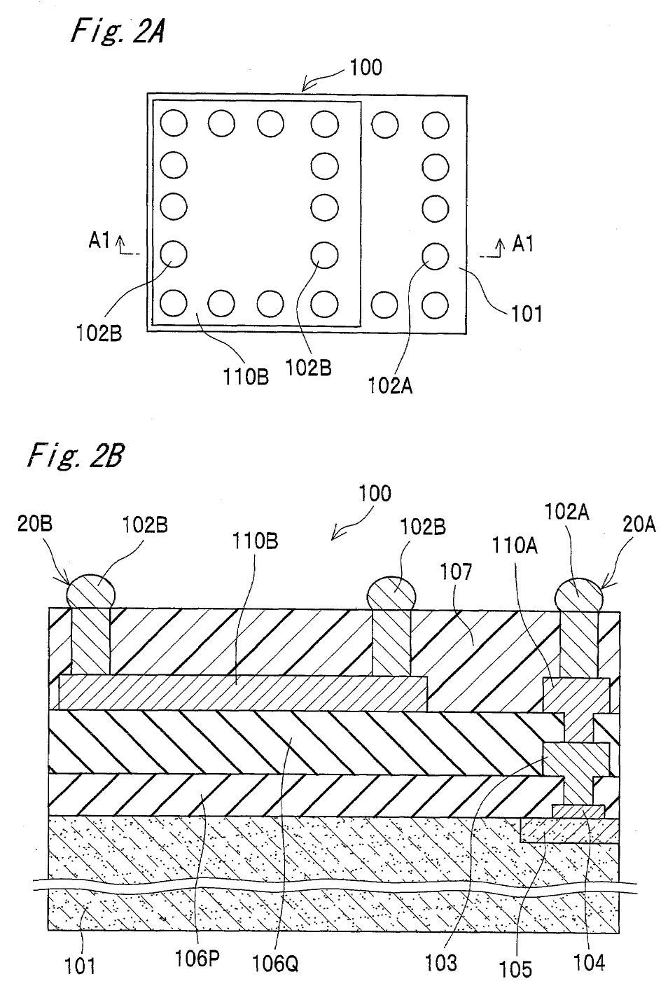

FIG. 2A is a plan view of a semiconductor 100 device according to a second embodiment of the invention, and FIG. 2B is a section view through line A1-A1 in FIG. 2A. A sealing layer 107 is also disposed to the semiconductor device 100 shown in FIG. 2A.

In FIG. 2B the external contacts 102B are formed uniformly around the perimeter of the top conductor plate layer 110B. The top conductor layer 110B covers the semiconductor substrate 101, and is connected to the external contacts 102B disposed around the perimeter.

The internal circuit 105, the pads 104, the conductor layer 103, the top conductor layer 110A, and the external contacts 102A render an active element 20A. The top conductor layer 110B and the perimeter external contacts 102B render a shielding element 20B. The semiconductor device 100 includes the dielectric layers 106P and 106Q, the active element 20A, and the shielding element 20B. The shielding element 20B is physically separated and electrically isolated from the active element 20A by the dielectric layers 106P and 106Q.

By rendering the top conductor layer 110B as a flat plate, this embodiment of the invention electrostatically isolates the lower conductor layer 103 and internal circuit 105 from the top layer. As a result, the parasitic coupling capacitance between the conductor layer 103 and internal circuit 105 and the printed wiring board of the wireless device disposed above the top conductor layer 110B by way of the intervening external contacts 102A and 102B can be greatly reduced. Resonance frequency variations and other adverse effects on the conductor layer 103 and the internal circuit 105 from the wiring board on which the semiconductor device 100 is mounted can therefore be eliminated.

### Embodiment 3

Primarily the differences between this third embodiment of the invention and the foregoing first and second embodiments are described below. Other aspects of the arrangement, operation and effect of this embodiment of the invention are the same as in the first and second embodiments, and further description thereof is thus omitted.

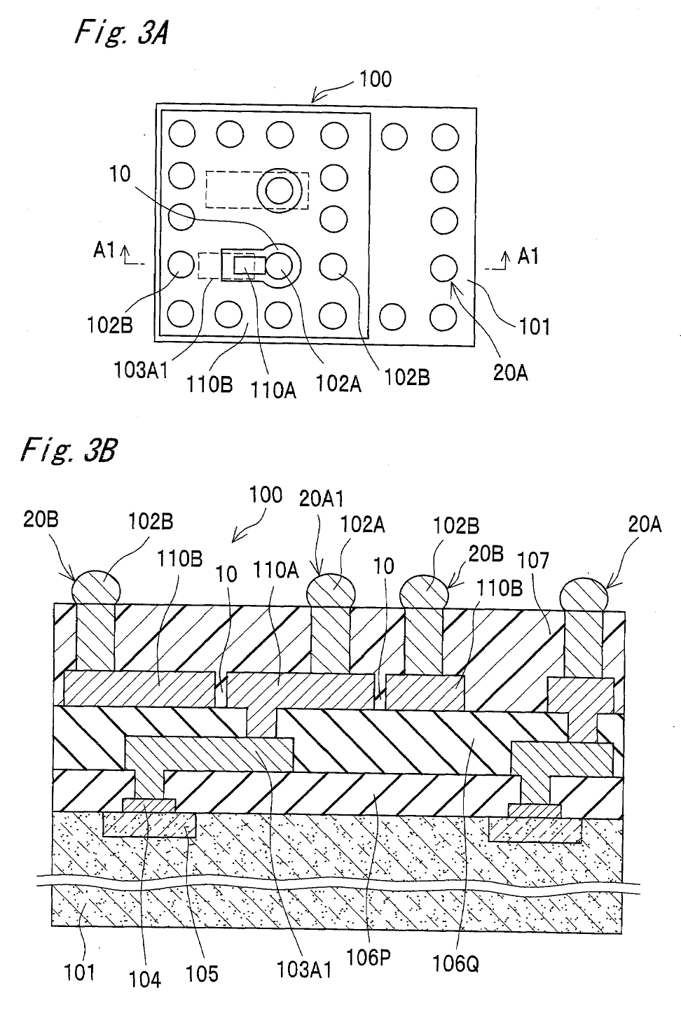

FIG. 3A is a plan view of a semiconductor 100 device according to a third embodiment of the invention, and FIG. 3B is a section view through line A1-A1 in FIG. 3A. A sealing layer 107 is also disposed to the semiconductor device 100 shown in FIG. 3A.

As shown in FIG. 3B a void 10 is formed in a part of the top conductor plate layer 110B, and a top conductor layer 110A that is isolated from the top conductor layer 110B is formed in the void 10 in substantially the same layer as the top conductor layer 110B. This top conductor layer 110A is connected to an external contact 102A formed on the top, and is connected to the internal circuit 105 on the semiconductor substrate 101 through an intervening conductor layer 103A1 and pad 104. The conductor layer 103A1 and the internal circuit 105 are located below the top conductor plate layer 110B.

The internal circuit 105, the pads 104, the conductor layer 103A1, the top conductor layer 110A, and the external contacts 102A render an active element 20A1. The top conductor layer 110B and the perimeter external contacts 102B render a shielding element 20B. The semiconductor device 100 includes the dielectric layers 106P and 106Q, the active element 20A1, and the shielding element 20B. The shielding element 20B is physically separated and electrically isolated from the active element 20A1 by the dielectric layers 106P and 106Q.

By rendering the top conductor layer 110B as a flat plate, this embodiment of the invention electrostatically isolates the lower conductor layer 103A1 and internal circuit 105 from the top layer. As a result, the parasitic coupling capacitance between the conductor layer 103A1 and internal circuit 105 and the printed wiring board of the wireless device disposed above the top conductor layer 110B by way of the intervening external contacts 102A and 102B can be greatly reduced. Resonance frequency variations and other adverse effects on the conductor layer 103A1 and the internal circuit 105 from the wiring board on which the semiconductor device 100 is mounted can therefore be eliminated.

### Embodiment 4

Primarily the differences between this fourth embodiment of the invention and the foregoing first to third embodiments are described below. Other aspects of the arrangement, operation and effect of this embodiment of the invention are the same as in the first to third embodiments, and further description thereof is thus omitted.

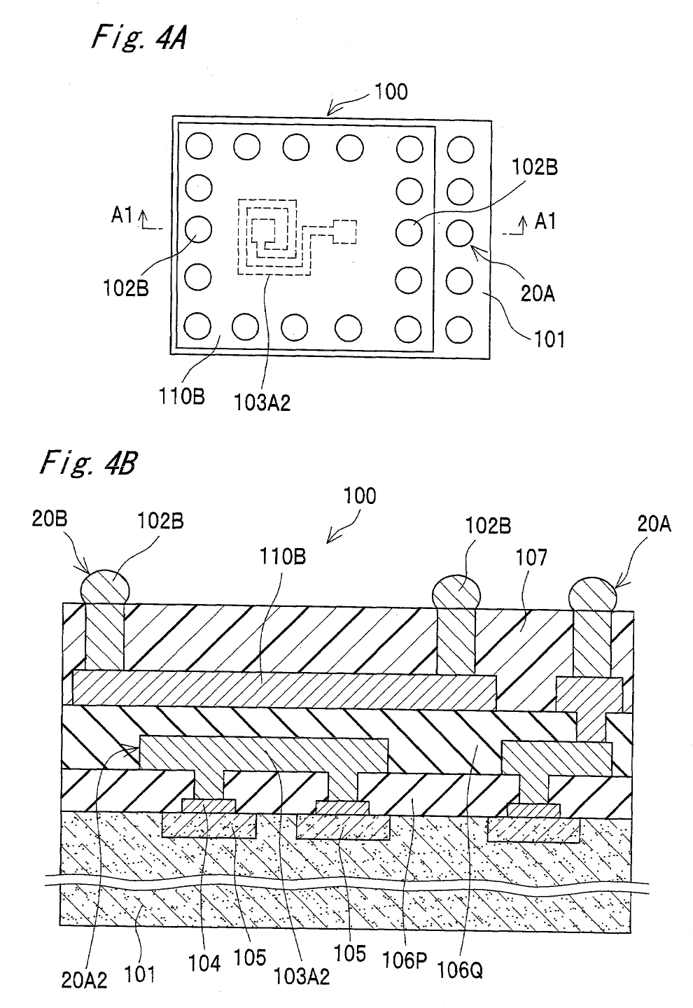

FIG. 4A is a plan view of a semiconductor 100 device according to a fourth embodiment of the invention, and FIG. 4B is a section view through line A1-A1 in FIG. 4A. A sealing layer 107 is also disposed to the semiconductor device 100 shown in FIG. 4A.

As shown in FIG. 4B a conductor layer 103A2 in which an inductor or other functional element is formed is disposed below the top conductor plate layer 110B. This inductor is spiral shaped and has both ends connected to the internal circuit 105 through pads 104. The conductor layer 103A2 and the internal circuit 105 are located below the top conductor plate layer 110B.

The internal circuit 105, the pads 104, and the conductor layer 103A2 render an active element 20A2. The top conductor layer 110B and the perimeter external contacts 102B render a shielding element 20B. The semiconductor device 100 includes the dielectric layers 106P and 106Q, the active element 20A2, and the shielding element 20B. The shielding element 20B is physically separated and electrically isolated from the active element 20A2 by the dielectric layers 106P and 106Q.

By rendering the top conductor layer 110B as a flat plate, this embodiment of the invention electrostatically isolates the inductor or other functional element rendered in the lower conductor layer 103A2 from the top layer. As a result, the parasitic coupling capacitance between the conductor layer 103A2 and internal circuit 105 and the printed wiring board of the wireless device disposed above the top conductor layer 110B by way of the intervening external contacts 102A and 102B can be greatly reduced. Resonance frequency variations and other adverse effects on the conductor layer 103A2 and the internal circuit 105 from the wiring board on which the semiconductor device 100 is mounted can therefore be eliminated.

### Embodiment 5

Primarily the differences between this fifth embodiment of the invention and the foregoing first to fourth embodiments are described below. Other aspects of the arrangement, operation and effect of this embodiment of the invention are the same as in the first to fourth embodiments, and further description thereof is thus omitted.

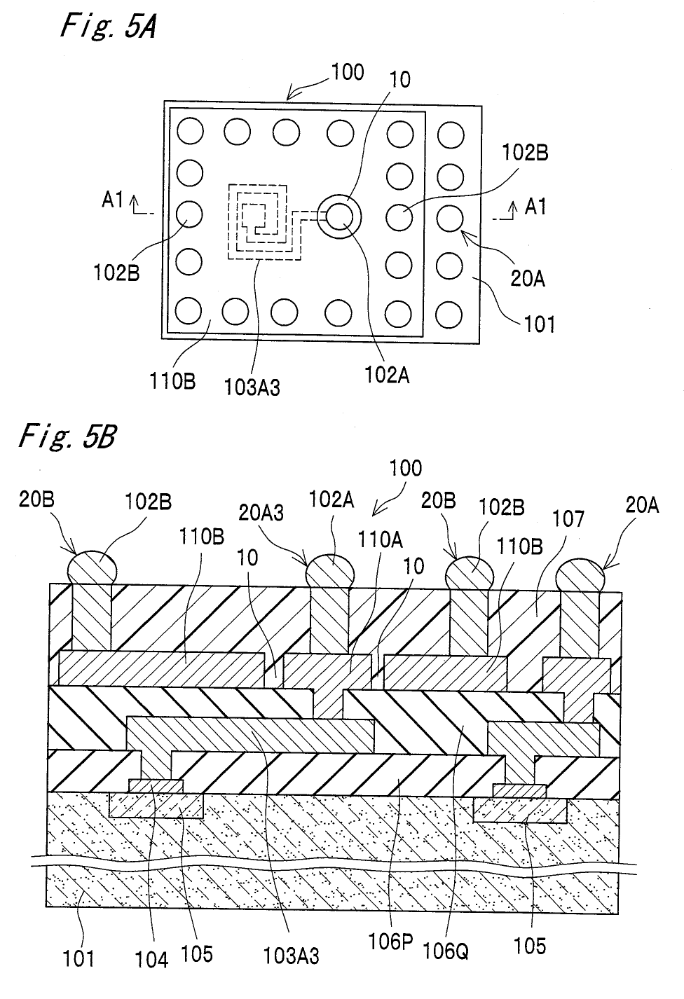

FIG. 5A is a plan view of a semiconductor 100 device according to the fifth embodiment of the invention, and FIG. 5B is a section view through line A1-A1 in FIG. 5A. A sealing layer 107 is also disposed to the semiconductor device 100 shown in FIG. 5A.

As shown in FIG. 5B a void 10 is formed in a part of the top conductor plate layer 110B, and a top conductor layer 110A that is isolated from the top conductor layer 110B is formed in the void 10 in substantially the same layer as the top conductor layer 110B. This top conductor layer 110A is connected to an external contact 102A formed on the top, and is connected to the internal circuit 105 on the semiconductor substrate 101 through an intervening conductor layer 103A2 and pad 104.

A spiraled inductor is formed in the conductor layer 103A3. The end of the inductor at the inside of the spiral is connected to the internal circuit 105 by a pad 104, and the other end is connected to the conductor layer 110A. The conductor layer 103A3 and the internal circuit 105 are located below the top conductor plate layer 110B.

The internal circuit 105, the pads 104, the conductor layer 103A3, the top conductor layer 110A, and the external contact 102A render an active element 20A3. The top conductor layer 110B and the perimeter external contacts 102B render a shielding element 20B. The semiconductor device 100 includes the dielectric layers 106P and 106Q, the active element 20A3, and the shielding element 20B. The shielding element 20B is physically separated and electrically isolated from the active element 20A3 by the dielectric layers 106P and 106Q.

By rendering the top conductor layer 110B as a flat plate, this embodiment of the invention electrostatically isolates the inductor or other functional element rendered in the lower conductor layer 103A3 from the top layer. As a result, the parasitic coupling capacitance between the conductor layer 103A3 and internal circuit 105 and the printed wiring board of the wireless device disposed above the top conductor layer 110B by way of the intervening external contacts 102A and 102B can be greatly reduced. Resonance frequency variations and other adverse effects on the conductor layer 103A3 and the internal circuit 105 from the wiring board on which the semiconductor device 100 is mounted can therefore be eliminated.

### Embodiment 6

Primarily the differences between this sixth embodiment of the invention and the foregoing first to fifth embodiments are described below. Other aspects of the arrangement, operation and effect of this embodiment of the invention are the same as in the first to fifth embodiments, and further description thereof is thus omitted.

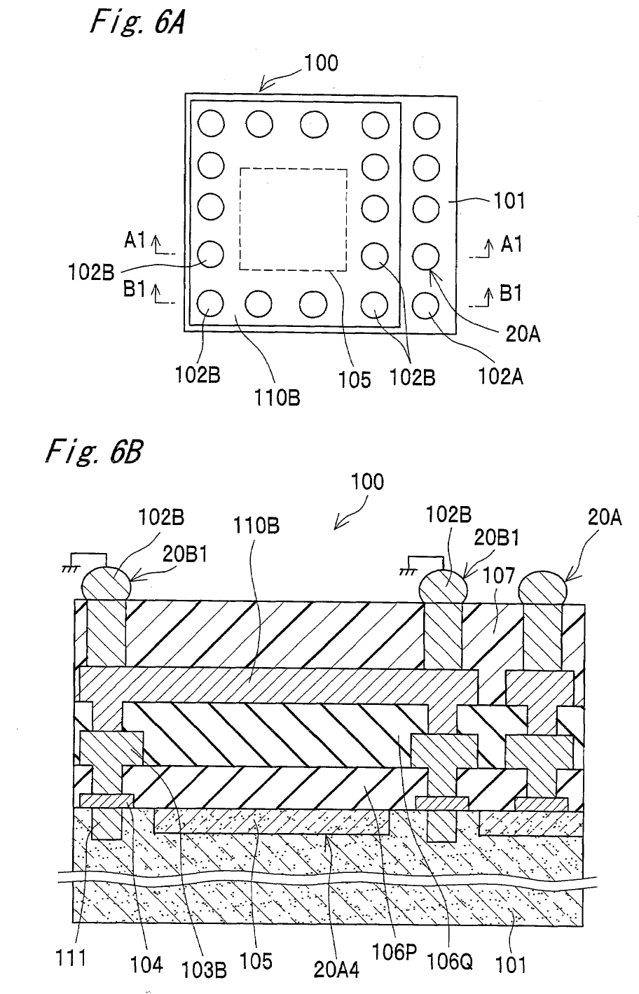

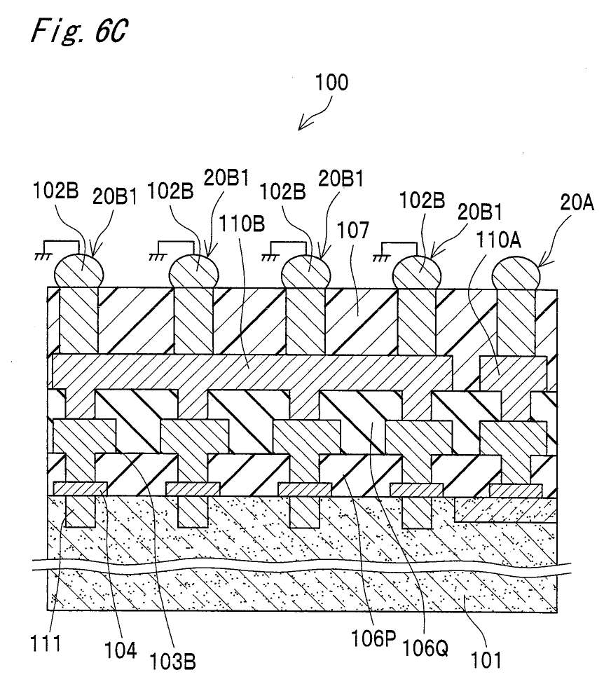

FIG. 6A is a plan view of a semiconductor 100 device according to the sixth embodiment of the invention, and FIG. 6B is a section view through line A1-A1 in FIG. 6A. A sealing layer 107 is also disposed to the semiconductor device 100 shown in FIG. 6A. FIG. 6C is a section view through line B1-B1 in FIG. 6A, and also shows the sealing layer 107 disposed to the top of the semiconductor device 100 shown in FIG. 6A.

As shown in FIG. 6B the internal circuit 105 of the semiconductor substrate 101 is disposed below the top conductor plate layer 110B in this aspect of the invention. The top conductor layer 110B goes to ground through an external contact 102B formed on top, and is connected to the semiconductor substrate 101 on the bottom through a conductor layer 103B, pad 104, and a ground conductor 111.

As shown in FIG. 6C, the external contacts 102B are connected to the perimeter of the top conductor layer 110B and on the bottom to the semiconductor substrate 101 as described in FIG. 6B.

The internal circuit 105 renders an active element 20A4. The ground conductor 111, the pad 104, the conductor layer 103B, the top conductor layer 110B, and the perimeter external contacts 102B render a shielding element 20B1.

The semiconductor device 100 includes a semiconductor substrate 101, dielectric layers 106P and 106Q, the active element 20A4, and the shielding element 20B1. The shielding element 20B1 is physically separated and electrically isolated from the active element 20A4 by the dielectric layers 106P and 106Q.

The gap between the shielding elements 20B1, or more specifically the gap between the external contacts 102B, is se to provide sufficient protection against electromagnetic waves in the frequency band that is used. From a first consideration this gap is set to less than or equal to ¼ the wavelength of the used frequency. From a second consideration the gap is set to less than or equal to ¼ the wavelength of the frequency that is twice or three times higher than the used frequency. From a third consideration the gap is set to less than or equal to ½ the height of the shielding element 20B1 with consideration for the waveguide shielding frequency.

If the frequency of 2 GHz is used, the gap is less than or equal to 3.75 cm according to the first consideration, and less than or equal to 1.87 cm at twice the frequency and less than or equal to 1.25 cm at three times the frequency according to the second consideration. If the height of the shielding element 20B1 is 0.105 mm, for example, the gap is less than or equal to 0.21 mm according to the third consideration.

The gap between the shielding element 20B1 is therefore preferably less than or equal to 3.75 cm, further preferably less than or equal to 1.25 cm, and yet further preferably less than or equal to 0.21 mm.

By rendering the top conductor layer 110B as a flat plate, this embodiment of the invention electrostatically isolates the internal circuit 105 on the bottom semiconductor substrate 101 from the top layer. As a result, the parasitic coupling capacitance between the internal circuit 105 and the printed wiring board of the wireless device disposed above the top conductor layer 110B by way of the intervening external contacts 102A and 102B can be greatly reduced. Resonance frequency variations and other adverse effects on the internal circuit 105 from the wiring board on which the semiconductor device 100 is mounted can therefore be eliminated.

The area surrounded by the shielding elements 20B1 connected at the bottom end to the semiconductor substrate 101 and grounded at the top end is also electromagnetically shielded from the other part of the semiconductor device 100. Electromagnetic interference from the active element 20A on the internal circuit 105 is also reduced.

### Embodiment 7

Primarily the differences between this seventh embodiment of the invention and the foregoing first to sixth embodiments are described below. Other aspects of the arrangement, operation and effect of this embodiment of the invention are the same as in the first to sixth embodiments, and further description thereof is thus omitted.

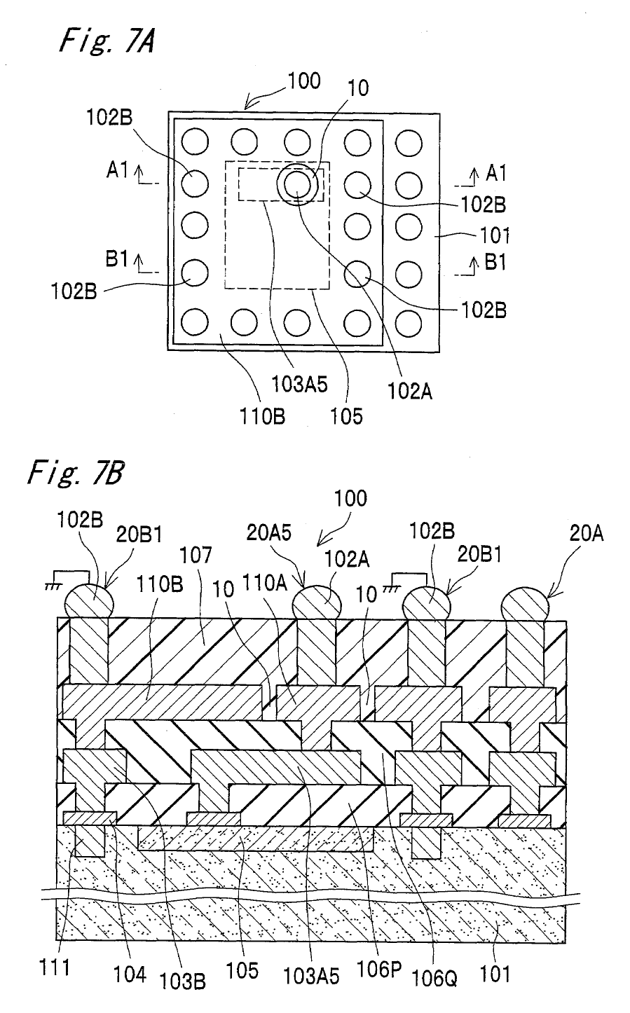

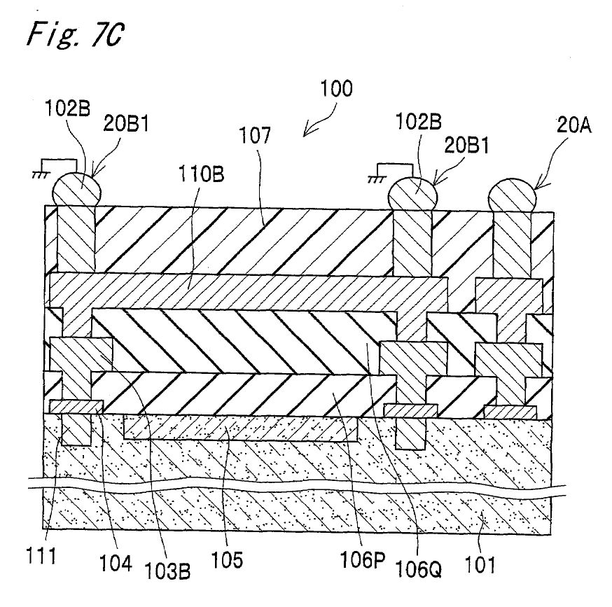

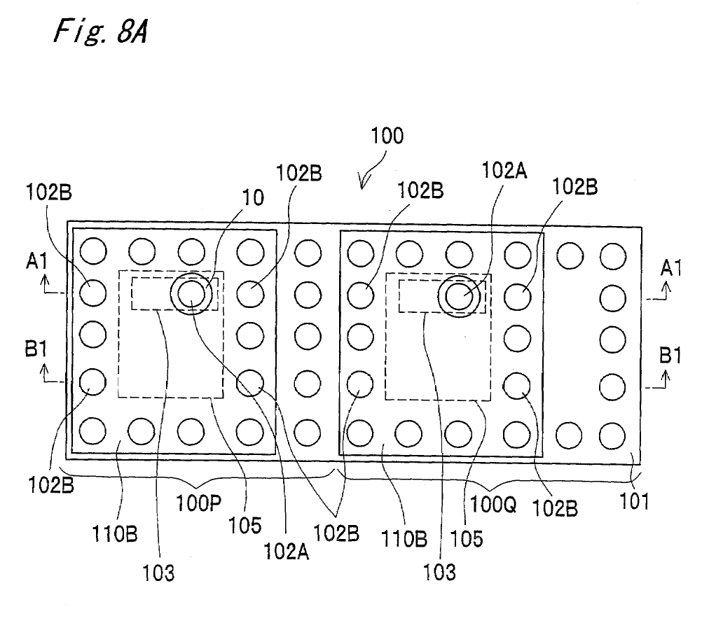

FIG. 7A is a plan view of a semiconductor 100 device according to the sixth embodiment of the invention, and FIG. 7B is a section view through line A1-A1 in FIG. 7A. A sealing layer 107 is also disposed to the semiconductor device 100 shown in FIG. 7A. FIG. 7C is a section view through line B1-B1 in FIG. 7A, and also shows the sealing layer 107 disposed to the top of the semiconductor device 100 shown in FIG. 7A.

As shown in FIG. 7B a void 10 is formed in a part of the top conductor plate layer 110B, and a top conductor layer 110A that is isolated from the top conductor layer 110B is formed in the void 10 in substantially the same layer as the top conductor layer 110B. This top conductor layer 110A is connected to an external contact 102A formed on the top, and is connected to the internal circuit 105 on the semiconductor substrate 101 through an intervening conductor layer 103A5 and pad 104. The conductor layer 103A5 and the internal circuit 105 are located below the top conductor plate layer 110B.

The top conductor layer 110B goes to ground through an external contact 102B formed on top, and is connected to the semiconductor substrate 101 on the bottom through a conductor layer 103B, pad 104, and a ground conductor 111.

As shown in FIG. 7C, the external contacts 102B are connected to the perimeter of the top conductor layer 110B and on the bottom to the semiconductor substrate 101 as described in FIG. 7B.

The internal circuit 105, the pads 104, the conductor layer 103A5, the top conductor layer 110A, and the external contact 102A render an active element 20A5. The ground conductor 111, the pads 104, the conductor layer 103B, the top conductor layer 110B, and the perimeter external contacts 102B render a shielding element 20B1.

The semiconductor device 100 includes a semiconductor substrate 101, dielectric layers 106P and 106Q, the active element 20A5, and the shielding element 20B1. The shielding element 20B1 is physically separated and electrically isolated from the active element 20A5 by the dielectric layers 106P and 106Q.

By rendering the top conductor layer 110B as a flat plate, this embodiment of the invention electrostatically isolates the lower conductor layer 103A5 and internal circuit 105 from the top layer. As a result, the parasitic coupling capacitance between the conductor layer 103A5 and internal circuit 105 and the printed wiring board of the wireless device disposed above the top conductor layer 110B by way of the intervening external contacts 102A and 102B can be greatly reduced. Resonance frequency variations and other adverse effects on the conductor layer 103A5 and internal circuit 105 from the wiring board on which the semiconductor device 100 is mounted can therefore be eliminated.

The area surrounded by the shielding elements 20B1 connected at the bottom end to the semiconductor substrate 101 and to ground at the top end is also electromagnetically shielded from the other part of the semiconductor device 100. Electromagnetic interference from the active element 20A on the conductor layer 103A5 and the internal circuit 105 is also reduced. In addition, the output signal from the internal circuit 105 of the active element 20A5 can also be output through the external contact 102A from the semiconductor device 100 without being affected by electromagnetic interference from the active element 20A, for example.

### Embodiment 8

Primarily the differences between this eighth embodiment of the invention and the foregoing first to seventh embodiments are described below. Other aspects of the arrangement, operation and effect of this embodiment of the invention are the same as in the first to seventh embodiments, and further description thereof is thus omitted.

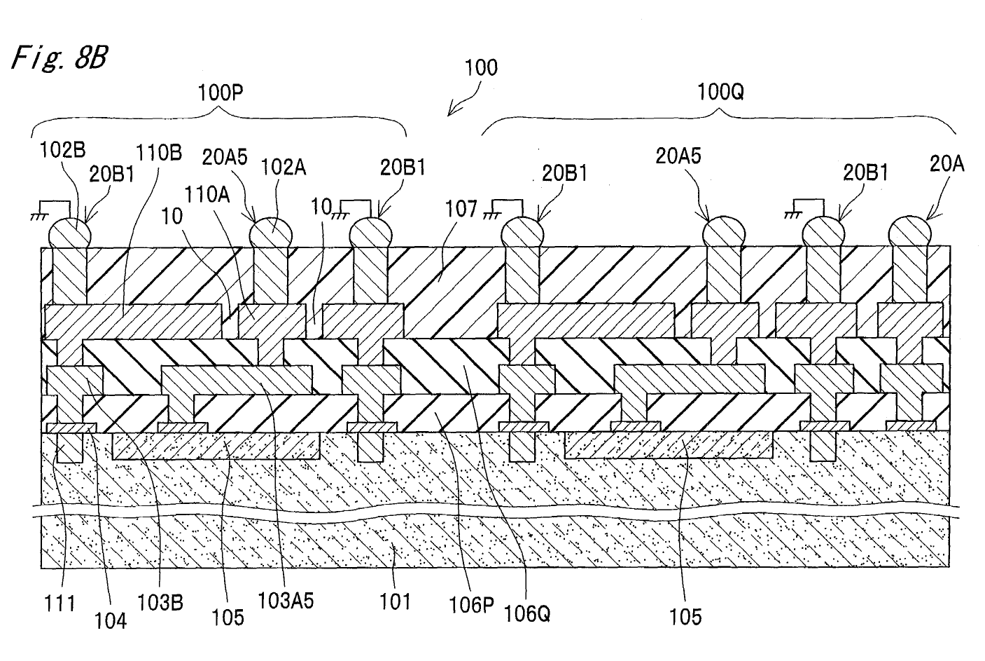

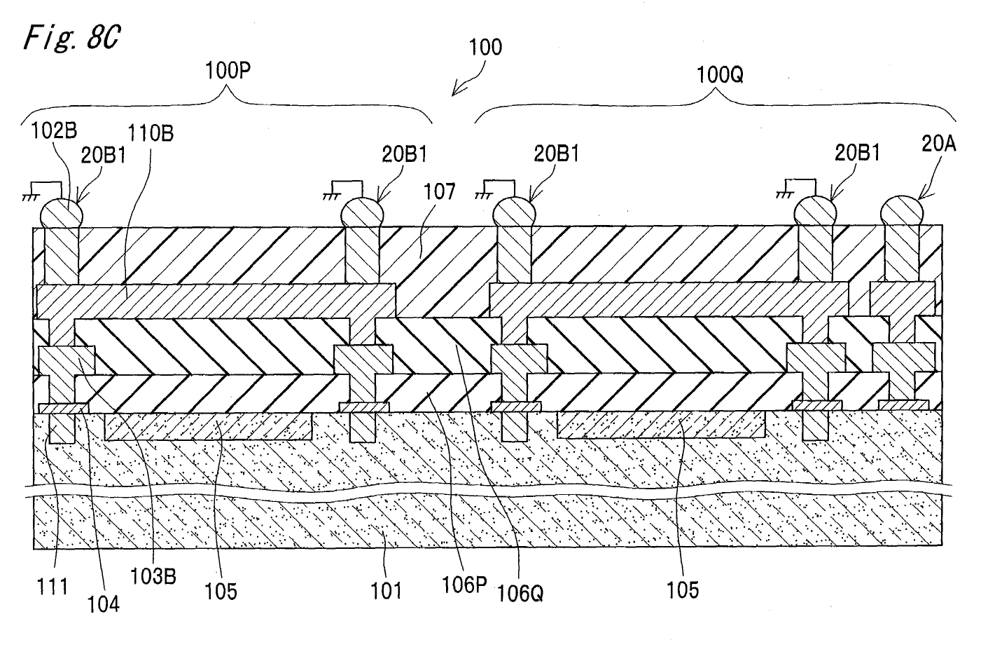

FIG. 8A is a plan view of a semiconductor 100 device according to the seventh embodiment of the invention, and FIG. 8B is a section view through line A1-A1 in FIG. 8A. A sealing layer 107 is also disposed to the semiconductor device 100 shown in FIG. 8A. FIG. 8C is a section view through line B1-B1 in FIG. 8A, and also shows the sealing layer 107 disposed to the top of the semiconductor device 100 shown in FIG. 8A.

The semiconductor device 100 according to this eighth embodiment of the invention has semiconductor devices 100P and 100Q each identical to the semiconductor device 100 according to the foregoing seventh embodiment. The internal circuit 105 included in each of the semiconductor devices 100P and 100Q can be different circuits.

By rendering the top conductor layer 110B as a flat plate in the semiconductor devices 100P and 100Q, this embodiment of the invention electrostatically isolates the lower conductor layer 103A5 and internal circuit 105 from the top layer. As a result, the parasitic coupling capacitance between the conductor layer 103A5 and internal circuit 105 and the printed wiring board of the wireless device disposed above the top conductor layer 110B by way of the intervening external contacts 102A and 102B can be greatly reduced in both of the semiconductor devices 100P and 100Q. Resonance frequency variations and other adverse effects on the conductor layer 103A5 and internal circuit 105 from the wiring board on which the semiconductor device 100 is mounted can therefore be eliminated.

The semiconductor devices 100P and 100Q that are surrounded by the shielding elements 20B1 connected at the bottom end to the semiconductor substrate 101 and to ground at the top end are also electromagnetically shielded from each other. Electromagnetic interference from the conductor layer 103A5 and the internal circuit 105 in one semiconductor device on the conductor layer 103A5 and the internal circuit 105 in the other semiconductor device can also be reduced. In addition, the output signal from the internal circuit 105 of one active element 20A5 can also be output through the external contact 102A from the semiconductor device 100 without being affected by electromagnetic interference from the conductor layer 103A5 and the internal circuit 105 in the other semiconductor device 100. Interference between two semiconductor devices 100P and 100Q rendered on the same wafer can thus be reduced.

It will be obvious to one with ordinary skill in the related art that two, three or more semiconductor devices 100 according to the foregoing seventh embodiment can be arranged and described as in this embodiment of the invention.

### Embodiment 9

Primarily the differences between this ninth embodiment of the invention and the foregoing first to eighth embodiments are described below. Other aspects of the arrangement, operation and effect of this embodiment of the invention are the same as in the first to eighth embodiments, and further description thereof is thus omitted.

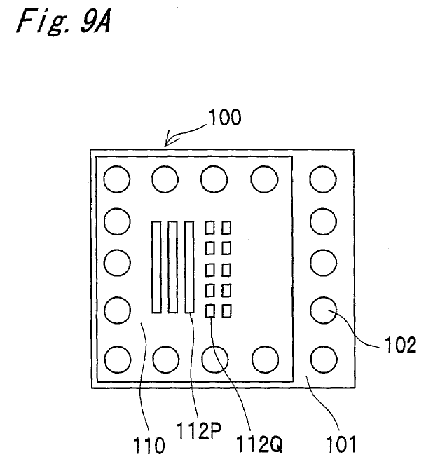

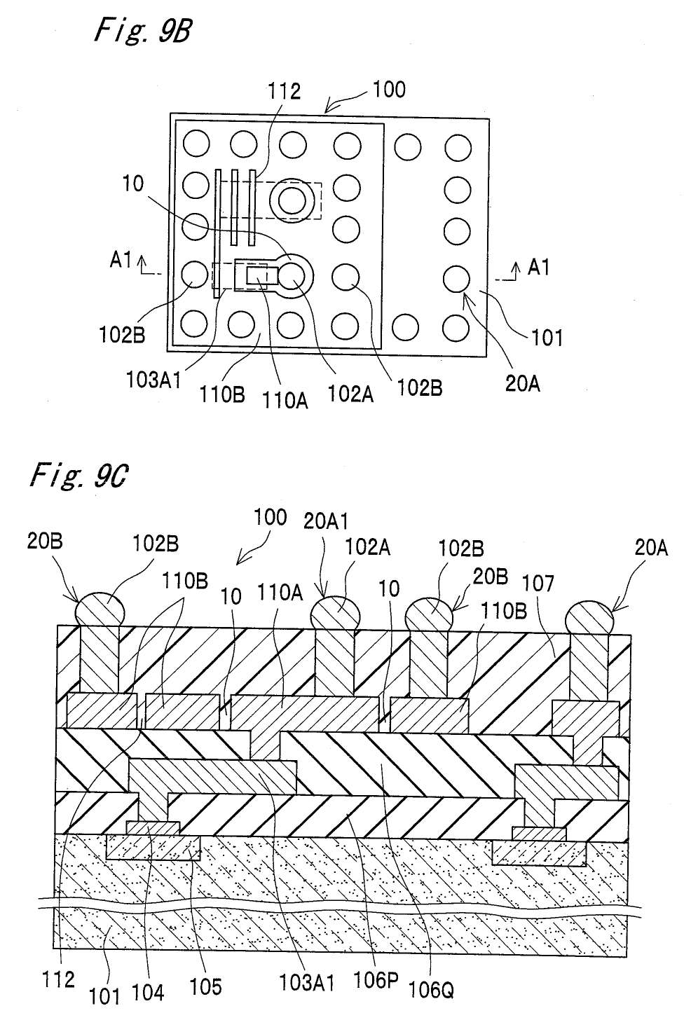

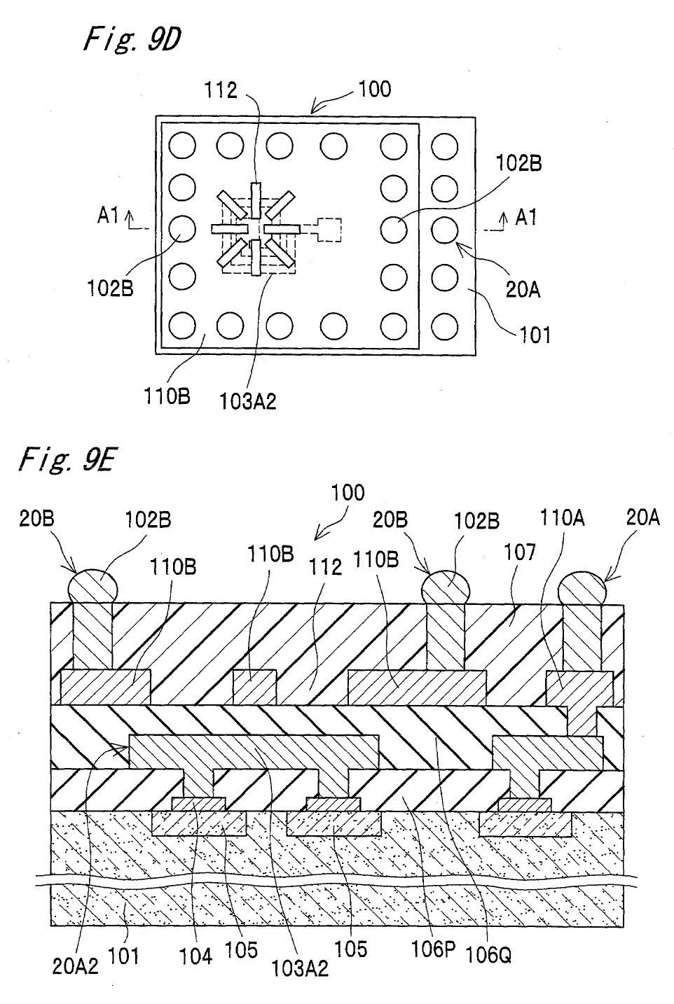

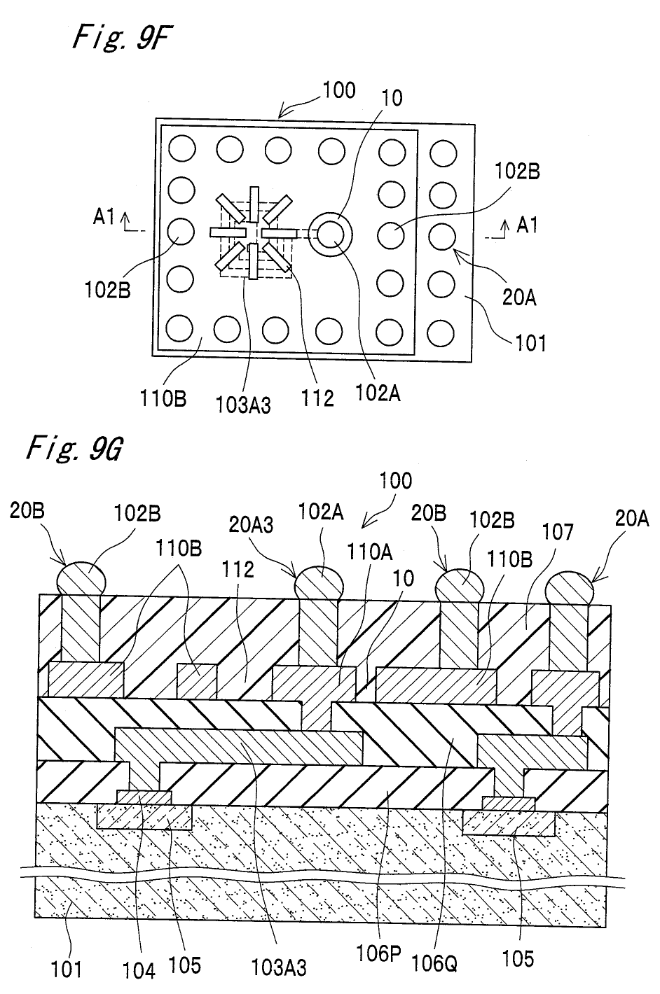

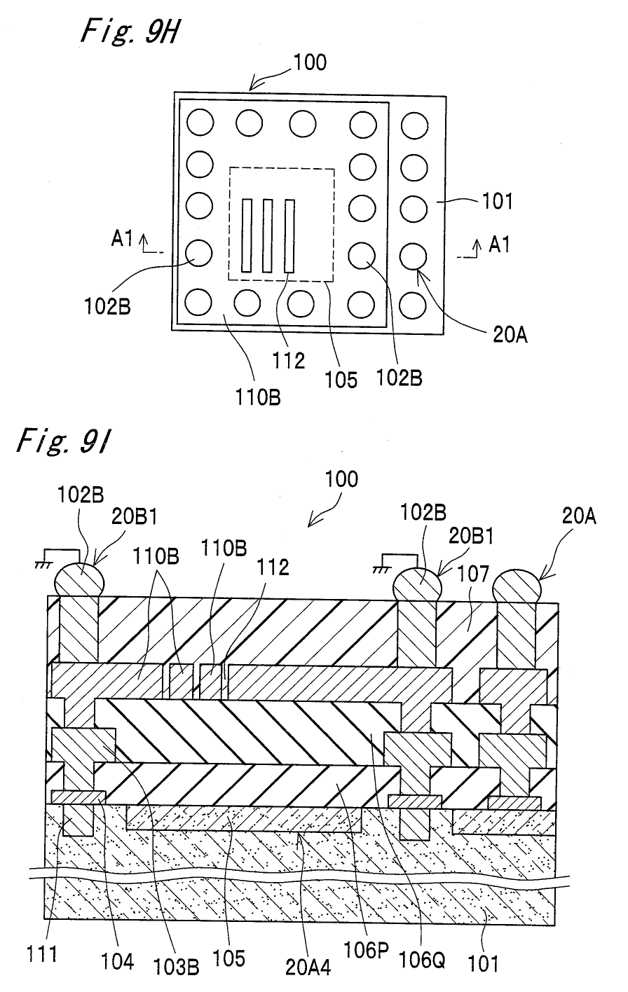

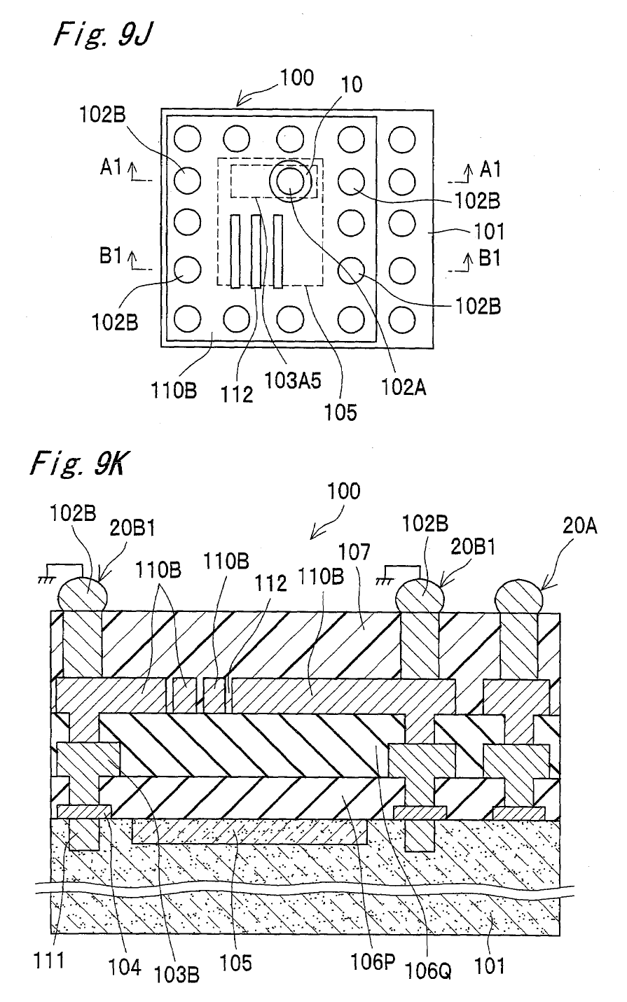

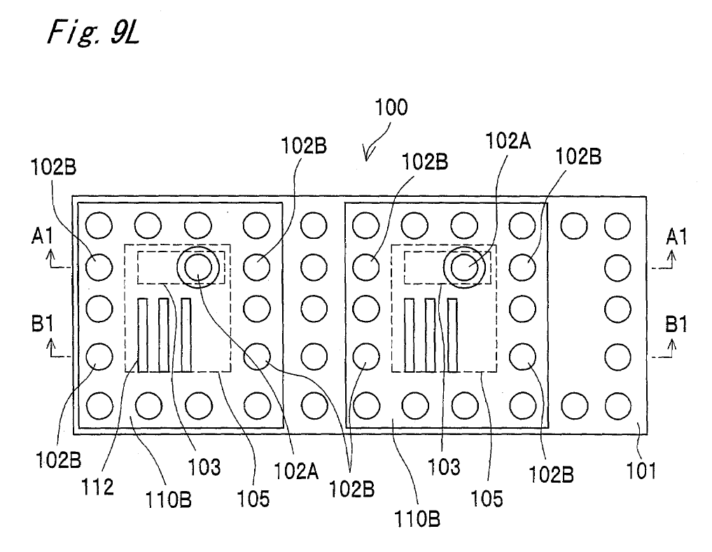

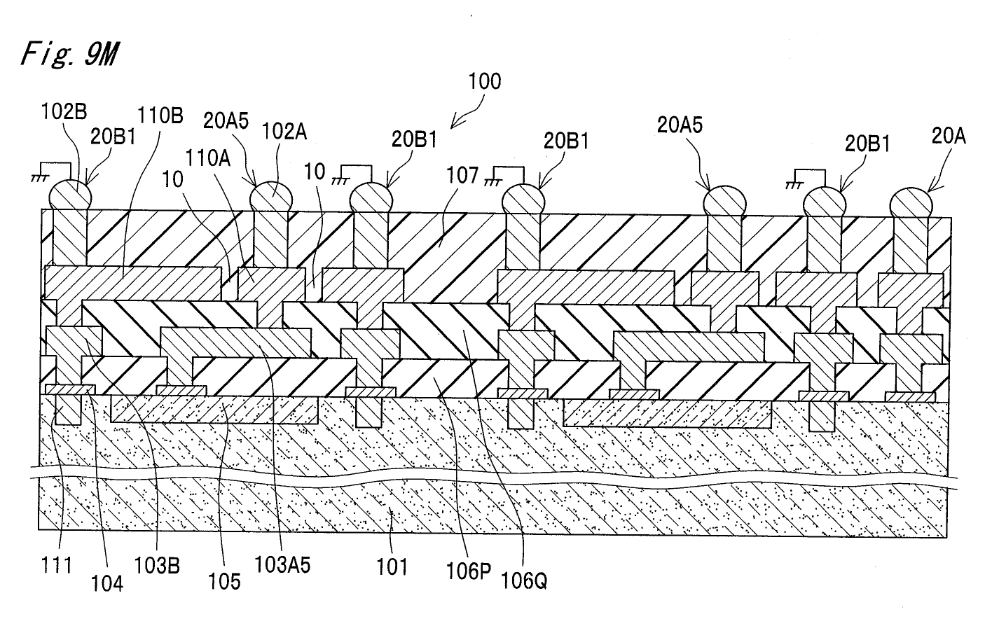

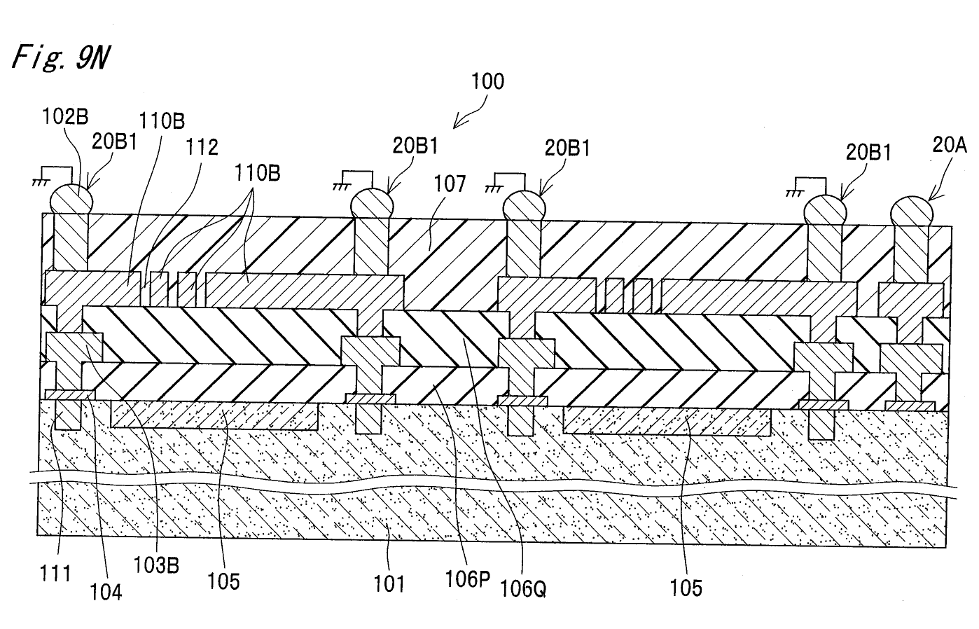

FIG. 9A is a plan view of the semiconductor device 100 described in the foregoing first and second embodiments in which at least one slit 112P of which the long side is comparatively long, and at least one slit 112Q of which the long side is comparatively short, are rendered in a part of the top conductor plate layer 110B. These slits are also referred to as “openings.”

FIG. 9B is a plan view of the semiconductor device 100 described in the foregoing third embodiment in which at least one slit 112 is rendered in a part of the top conductor plate layer 110B.

FIG. 9C is a section view through line A1-A1 in FIG. 9B.

FIG. 9D is a plan view of the semiconductor device 100 described in the foregoing fourth embodiment in which at least one slit 112 is rendered in a part of the top conductor plate layer 110B. These one or more slits 112 are in a layer above the inductor formed in the conductor layer 103A2, and are arranged radiating from the center of the inductor spiral.

FIG. 9E is a section view through line A1-A1 in FIG. 9D.

FIG. 9F is a plan view of the semiconductor device 100 described in the foregoing fifth embodiment in which at least one slit 112 is rendered in a part of the top conductor plate layer 110B. These one or more slits 112 are in a layer above the inductor formed in the conductor layer 103A3, and are arranged radiating from the center of the inductor spiral.

FIG. 9G is a section view through line A1-A1 in FIG. 9F.

FIG. 9H is a plan view of the semiconductor device 100 described in the foregoing sixth embodiment in which at least one slit 112 is rendered in a part of the top conductor plate layer 110B. These one or more slits 112 are in a layer above the internal circuit 105.

FIG. 9I is a section view through line A1-A1 in FIG. 9H.

FIG. 9J is a plan view of the semiconductor device 100 described in the foregoing seventh embodiment in which at least one slit 112 is rendered in a part of the top conductor plate layer 110B.

FIG. 9K is a section view through line B1-B1 in FIG. 9J.

A section view through line A1-A1 in FIG. 9J is identical to FIG. 7B.

FIG. 9L is a plan view of the semiconductor device 100 described in the foregoing eighth embodiment in which at least one slit 112 is rendered in a part of the top conductor plate layer 110B.

FIG. 9M is a section view through line A1-A1 in FIG. 9L.

FIG. 9N is a section view through line B1-B1 in FIG. 9L.

By rendering one or more slits 112 in the top conductor plate layer 110B, these ninth embodiments of the invention alleviate stress in the top conductor plate layer 110B, and thus enable rendering a conductor layer with a plate-shaped area.

The top conductor plate layer 110B containing at least one slit 112 is located above the inductor rendered by the conductor layers 103A2 and 103A3. As a result, mutual inductance from the inductors produces an eddy current in the top conductor layer 110B. The field produced by this eddy current changes the inductance of the inductor and lowers the Q, but because the slits 112 reduce the eddy current, the change in inductance is reduced and the Q can be increased.

### Embodiment 10

Primarily the differences between this tenth embodiment of the invention and the foregoing first to ninth embodiments are described below. Other aspects of the arrangement, operation and effect of this embodiment of the invention are the same as in the first to ninth embodiments, and further description thereof is thus omitted.

This tenth embodiment of the invention describes a semiconductor device 100 called a wafer level chip size package (WLCSP) with substantially the same external dimensions as the semiconductor chip.

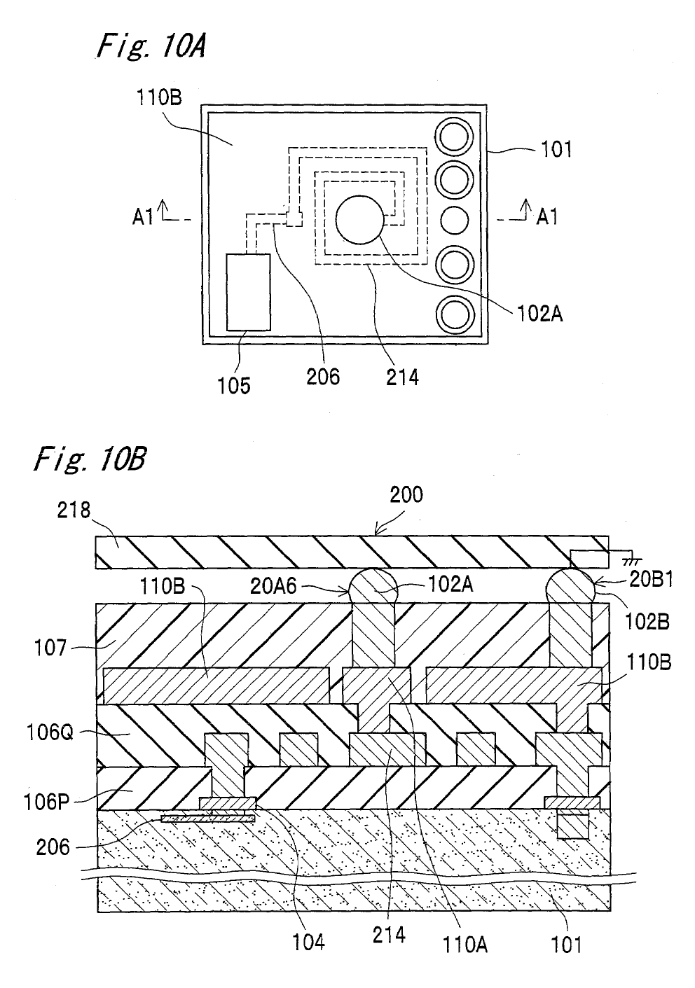

FIG. 10A is a schematic plan view showing some of the elements in a WLCSP arrangement of a semiconductor device 100 according to this tenth embodiment of the invention.

FIG. 10B is a schematic section view through line A1-A1 in FIG. 1A, and shows the sealing layer 107 that is additionally rendered over the arrangement shown in FIG. 10A, and the printed wiring board 218 of the wireless device connected to the external contacts 102A and 102B. FIG. 10B thus shows the arrangement of a wireless device 200 according to this embodiment of the invention. The side of the wireless device 200 to which the printed wiring board 218 is disposed at the top in FIG. 10B is referred to below as the top, and the side at the bottom of the figure where the semiconductor substrate 101 is disposed is referred to as the bottom.

This tenth embodiment of the invention also has a spiral shaped inductor 214 rendered in the conductor layer 103A3 as described in the foregoing fifth embodiment. The end of the inductor 214 at the center of the spiral is connected to the internal circuit 105 in the fifth embodiment, but in this embodiment of the invention is connected to the top conductor layer 110A. The other end of the inductor 214 is connected to the internal circuit 105 (not shown in FIG. 10B) by an aluminum line 206. The inductor 214 corresponds to the conductor layer 103A3 described in the fifth embodiment.

The internal circuit 105, the aluminum line 206, the pads 104, the inductor 214, the top conductor layer 110A, and the external contact 102A render an active element 20A6. As in the sixth embodiment the top conductor layer 110B is included in the shielding element 20B1. The shielding element 20B1 is physically separated and electrically isolated from the active element 20A6 by the dielectric layers 106P and 106Q. The active element 20A6 is connected to the printed wiring board 218 by way of intervening external contact 102A, and the shielding element 20B1 is connected to the printed wiring board 218 and to ground through external contact 102B.

By rendering the top conductor layer 110B as a flat plate, this embodiment of the invention electrostatically shields the lower inductor 214 from the top layer. As a result, the parasitic coupling capacitance between the printed wiring board 218 and the inductor 214 can be greatly reduced. Resonance frequency variations and other adverse effects on the inductor 214 from the printed wiring board 218 can therefore be eliminated. Furthermore, by rendering the inductor 214 in a spiral around the external contact 102A, this embodiment of the invention reduces the area occupied by the inductor 214 compared with the fifth embodiment.

More specifically, as shown in FIG. 10A, the top conductor plate layer 110B covers all of the semiconductor substrate 101, the inductor 214 is formed on the semiconductor substrate 101 to which the internal circuit 105 is rendered, and the dielectric layer 106Q intervenes between the top conductor layer 110B and the inductor 214. The external contact 102A is connected to the top conductor layer 110A and the inductor 214, and the inductor 214 spirals around the external contact 102A. One end of the inductor 214 is connected to the external contact 102A by way of the intervening the top conductor layer 110A, and the other end is connected to the internal circuit 105.

Yet more specifically, as shown in FIG. 10B, the semiconductor device 100 has a laminated structure in which the dielectric layer 106P, the dielectric layer 106Q, and the sealing layer 107 are sequentially deposited on the semiconductor substrate 101. The top conductor layer 110A passes through the dielectric layer 106Q, and the inductor 214 and the top conductor layer 110A are electrically connected with the top end exposed from the sealing layer 107 in the same plane as the surface of the sealing layer 107. The inductor 214 is formed as a conductive path spiraling around the post-shaped external contact 102A. The inductor 214 passes through the dielectric layer 106P, is electrically connected to a pad 104 on the surface of the semiconductor substrate 101, and is connected to the internal circuit 105 by the aluminum line 206 rendered on the semiconductor substrate 101.

By covering the entire surface above the inductor 214 with the top conductor plate layer 110B, this embodiment of the invention eliminates capacitance coupling caused by interlayer parasitic capacitance between the printed wiring board 218 and the inductor 214 layer, and the effect of noise from the printed wiring board 218 on the inductor 214 can be reduced.

### Embodiment 11

Primarily the differences between this eleventh embodiment of the invention and the foregoing tenth embodiment are described below. Other aspects of the arrangement, operation and effect of this embodiment of the invention are the same as in the tenth embodiment, and further description thereof is thus omitted.

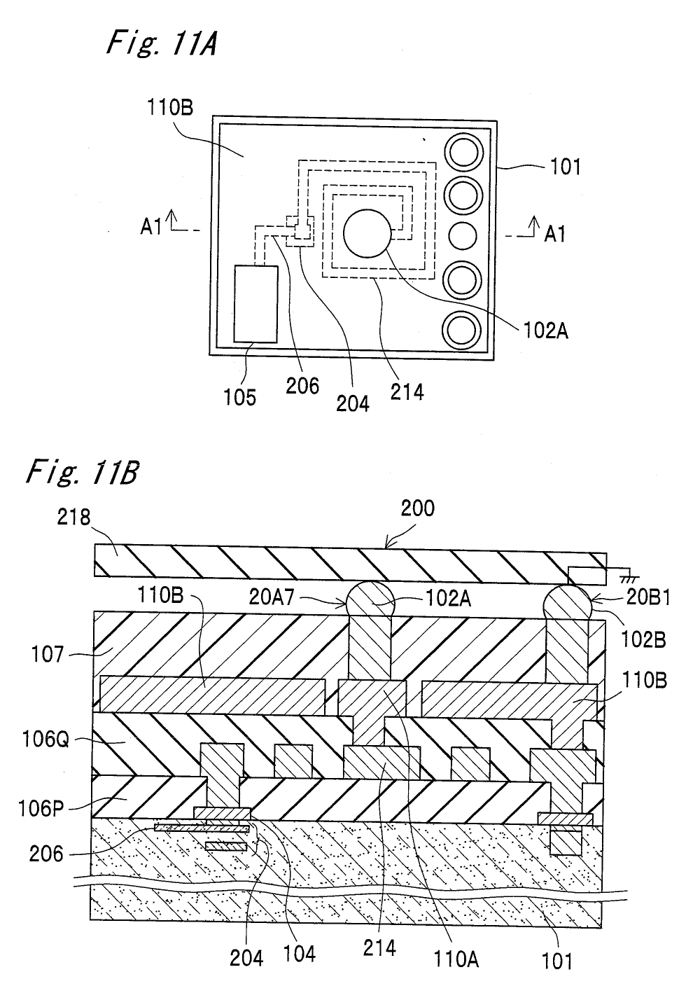

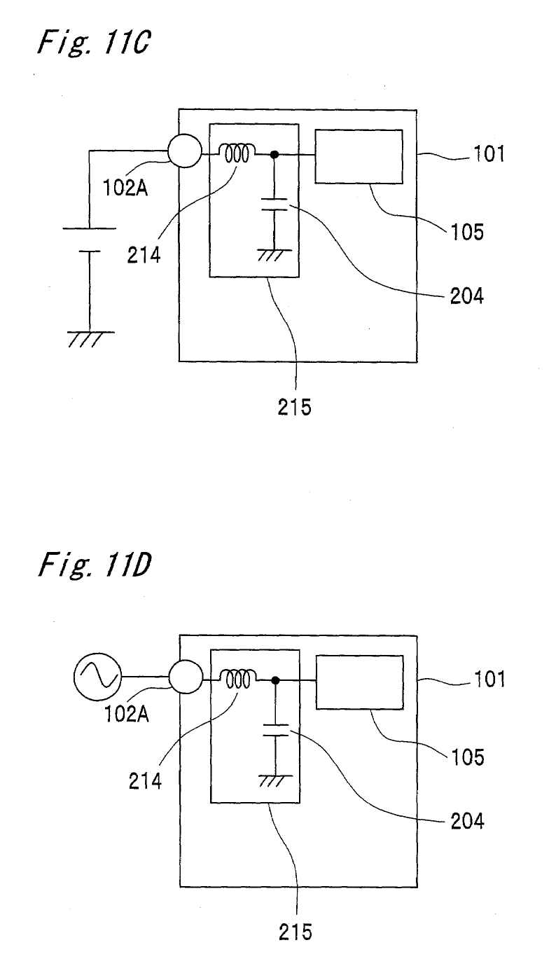

FIG. 11A is a schematic plan view showing some of the elements in a WLCSP arrangement of a semiconductor device 100 according to this eleventh embodiment of the invention.

FIG. 11B is a schematic section view through line A1-A1 in FIG. 11A, and shows the sealing layer 107 that is additionally rendered over the arrangement shown in FIG. 11A, and the printed wiring board 218 of the wireless device connected to the external contacts 102A and 102B. FIG. 11B thus shows the arrangement of a wireless device 200 according to this embodiment of the invention.

More specifically, as shown in FIG. 11A, the top conductor plate layer 110B covers all of the semiconductor substrate 101, the inductor 214 is formed by the conductor layer 103A3 on the semiconductor substrate 101 to which the internal circuit 105 is rendered, and the dielectric layer 106Q intervenes between the top conductor layer 110B and the inductor 214. The external contact 102A is connected to the top conductor layer 110A and the inductor 214, and the inductor 214 spirals around the external contact 102A. One end of the inductor 214 is connected to the external contact 102A by way of the intervening top conductor layer 110A, and the other end is connected to the internal circuit 105.

A capacitor 204 is connected to a node connected to the internal circuit 105 and one end is connected to the semiconductor substrate 101. The line connected to the internal circuit 105 is connected by the aluminum line 206 on the semiconductor substrate 101. The top conductor plate layer 110B is connected to the semiconductor substrate 101 through the pad 104.

Yet more specifically, as shown in FIG. 11B, the semiconductor device 100 has a laminated structure in which the dielectric layer 106P, the dielectric layer 106Q, and the sealing layer 107 are sequentially deposited on the semiconductor substrate 101. The top conductor layer 110A passes through the dielectric layer 106Q, and the inductor 214 and the top conductor layer 110A are electrically connected with the top end exposed from the sealing layer 107 in the same plane as the surface of the sealing layer 107. The inductor 214 is formed as a conductive path spiraling around the post-shaped external contact 102A. The inductor 214 passes through the dielectric layer 106P, is electrically connected to a pad 104 on the surface of the semiconductor substrate 101, and is connected to the internal circuit 105 and the capacitor 204 by the aluminum line 206 rendered on the semiconductor substrate 101. One side of the capacitor 204 is connected to the semiconductor substrate 101.

The internal circuit 105, the aluminum line 206, the capacitor 204, the pad 104, the inductor 214, the top conductor layer 110A, and the external contact 102A render an active element 20A7. As in the tenth embodiment the top conductor layer 110B is included in the shielding element 20B1. The shielding element 20B1 is physically separated and electrically isolated from the active element 20A7 by the dielectric layers 106P and 106Q. The active element 20A7 is connected to the printed wiring board 218 by way of intervening external contact 102A, and the shielding element 20B1 is connected to the printed wiring board 218 and to ground through external contact 102B.

The capacitor 204 can be rendered using any type of capacitance arrangement, including an MIM (metal-insulate-metal) structure, a gate oxide film capacitor, or an aluminum line-to-ground capacitance structure. FIG. 11B shows a simple MIM capacitor 204 by way of example.

By covering the entire surface above the inductor 214 with the top conductor plate layer 110B, this embodiment of the invention eliminates capacitance coupling caused by interlayer parasitic capacitance between the printed wiring board 218 and the inductor 214 layer, and the effect of noise from the printed wiring board 218 on the inductor 214 can be reduced.

In addition, disposing a capacitor 204 on the semiconductor substrate 101 and connecting the external contact 102A from the inductor 214 to the power supply reduces the effect of noise from the power supply on the internal circuit 105. Connecting the external contact 102A as an input/output terminal also enables use as a matching circuit. By using this eleventh embodiment of the invention as shown in FIG. 11C and FIG. 11D, this embodiment of the invention can be used internally without increasing the area of the semiconductor substrate 101. This is effective for reducing the size and cost of modern large-scale IC devices with many pins, and improves resistance to external noise from the power supply channel.

### Embodiment 12

Primarily the differences between this twelfth embodiment of the invention and the foregoing eleventh embodiment are described below. Other aspects of the arrangement, operation and effect of this embodiment of the invention are the same as in the eleventh embodiment, and further description thereof is thus omitted.

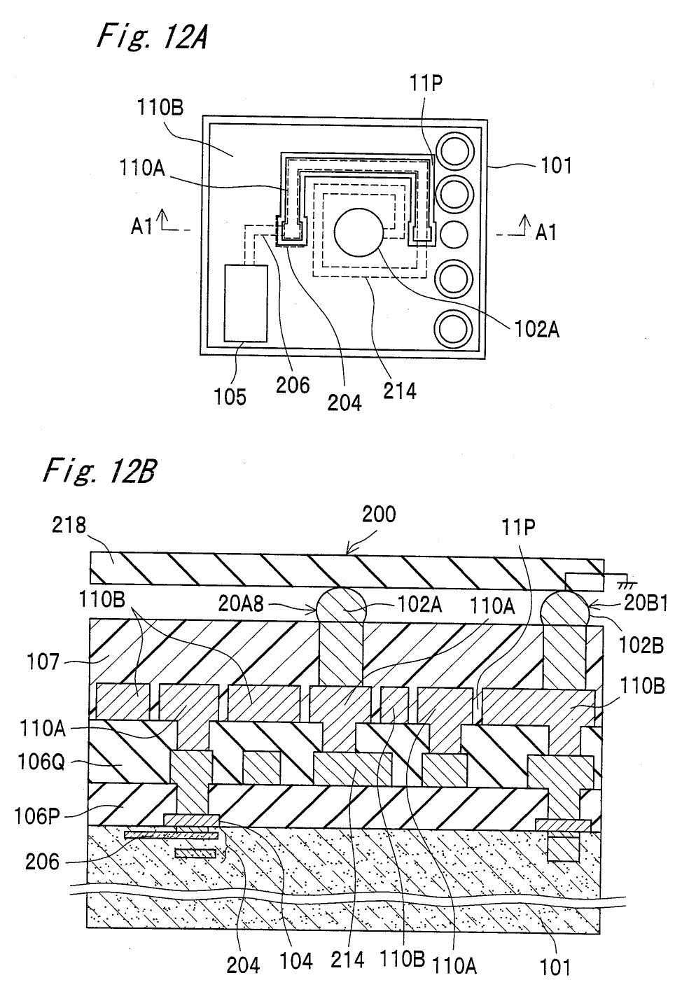

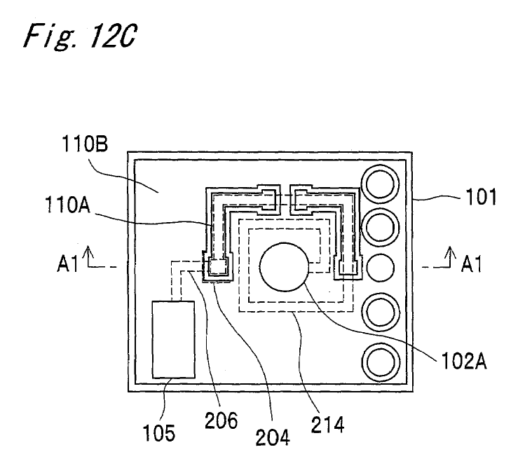

FIG. 12A is a schematic plan view showing some of the elements in a WLCSP arrangement of a semiconductor device 100 according to this eleventh embodiment of the invention.

FIG. 12B is a schematic section view through line A1-A1 in FIG. 12A, and shows the sealing layer 107 that is additionally rendered over the arrangement shown in FIG. 12A, and the printed wiring board 218 of the wireless device connected to the external contacts 102A and 102B. FIG. 12B thus shows the arrangement of a wireless device 200 according to this embodiment of the invention.

As shown in FIG. 11A, the eleventh embodiment of the invention renders an inductor 214 in the conductor layer 103A3 on the semiconductor substrate 101 on which the internal circuit 105 is formed.

In this twelfth embodiment as shown in FIG. 12A, the inductor 214 is rendered by the conductor layer 103A3 on the semiconductor substrate 101, and the conductor layer 110A is rendered directly above and parallel to part of the spiral shaped inductor 214. The conductor layer 110A is connected to a part of the inductor 214 and substantially the same width as the inductor 214. This inductor 214 and conductor layer 110A render a compound inductor 214A. The conductor layer 110A and the top conductor plate layer 110B are formed on the same surface and are separated by a slit 11P. The top conductor plate layer 110B cover the entire surface of the semiconductor substrate 101 except for the conductor layer 110A.

As in the eleventh embodiment the external contact 102A is connected to the conductor layer 110A and the inductor 214, and the inductor 214 spirals around the external contact 102A. The inductor 214 is connected midway to the conductor layer 110A, forming a parallel spiral. One end of the inductor 214 is connected to the external contact 102A by way of the intervening conductor layer 110A, and the other end is connected to the internal circuit 105.

A capacitor 204 is connected to a node connected to the internal circuit 105 and one end is connected to the semiconductor substrate 101. The line connected to the internal circuit 105 is connected by the aluminum line 206 on the semiconductor substrate 101.

More specifically, the external contact 102A shown in FIG. 12B is the same as in the eleventh embodiment.

The inductor 214 is isolated from the top conductor plate layer 110B by the dielectric layer 106Q, and is formed as a conductive path spiraling around the post-shaped external contact 102A. Midway through the conductive path the inductor 214 is electrically connected to the conductor layer 110A through the intervening dielectric layer 106Q. A slit 11P is formed in the top conductor plate layer 110B near the conductive path of the inductor 214. Other than at this slit 11P, the conductor layer 110B shields the rest of the underlying inductor 214 and the semiconductor substrate 101. The conductor layer 110A and inductor 214 rendering the compound inductor 214A form parallel spirals around the external contact 102A at the center.

The conductor layer 110A passes through the dielectric layer 106Q at the output node of the inductor 214, and is connected to the inductor 214. The inductor 214 additionally passes through the dielectric layer 106P, and is electrically connected to a pad 104 on the surface of the semiconductor substrate 101. The pad 104 is connected to the internal circuit 105 and the capacitor 204 through an aluminum line 206 on the semiconductor substrate 101. The other side of the capacitor 204 is connected to the semiconductor substrate 101.

The internal circuit 105, the aluminum line 206, the capacitor 204, the pad 104, the compound inductor 214A, the top conductor layer 110A, and the external contact 102A render an active element 20A8. As in the eleventh embodiment the top conductor layer 110B is included in the shielding element 20B1. The shielding element 20B1 is physically separated and electrically isolated from the active element 20A8 by the dielectric layers 106P and 106Q. The active element 20A8 is connected to the printed wiring board 218 by way of intervening external contact 102A, and the shielding element 20B1 is connected to the printed wiring board 218 and to ground through external contact 102B.

FIG. 12C shows a variation in which the conductor layer 110A rendering the compound inductor 214A is divided into multiple parts, each of which is electrically connected to the parallel inductor 214 formed below. The top conductor plate layer 110B is the same as in the eleventh embodiment. The capacitor 204 shown connected to the internal circuit 105 is also not necessarily provided, and the compound inductor 214A can be rendered without the capacitor 204.

By covering the entire surface above the inductor 214 with the top conductor plate layer 110B as in the eleventh embodiment, this embodiment of the invention prevents the printed wiring board 218 from affecting the inductor 214. In addition, by connecting the inductor 214 and the conductor layer 110A in parallel, this embodiment of the invention can reduce parasitic resistance and improve the Q of the inductor more effectively than the eleventh embodiment. Other effects of this embodiment are the same as the eleventh embodiment. Providing a slit as shown in FIG. 12C also provides more effective shielding to the printed wiring board 218.

### Embodiment 13

Primarily the differences between this thirteenth embodiment of the invention and the foregoing tenth embodiment are described below. Other aspects of the arrangement, operation and effect of this embodiment of the invention are the same as in the tenth embodiment, and further description thereof is thus omitted.

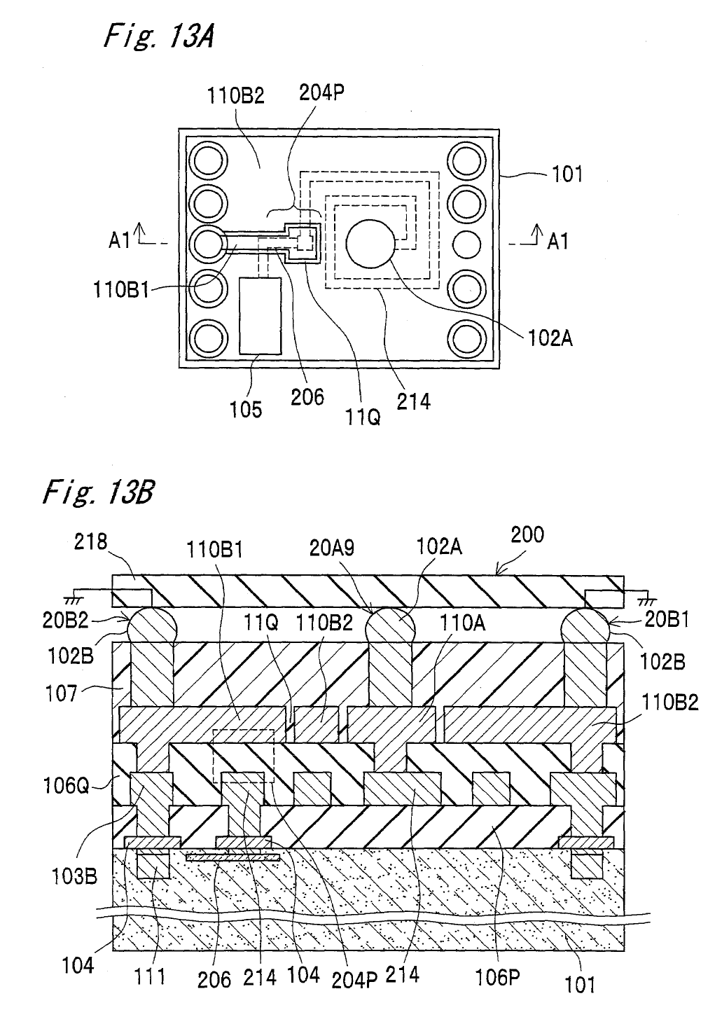

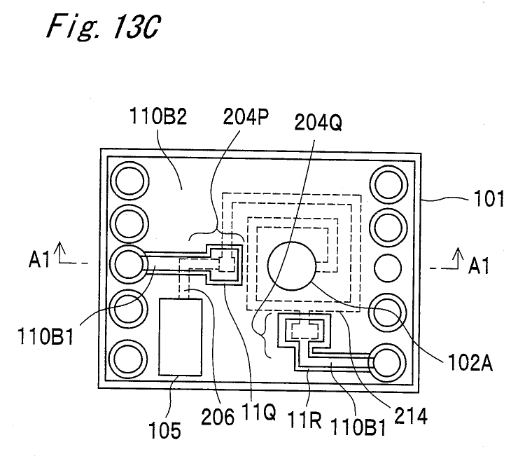

FIG. 13A is a schematic plan view showing some of the elements in a WLCSP arrangement of a semiconductor device 100 according to this eleventh embodiment of the invention.

FIG. 13B is a schematic section view through line A1-A1 in FIG. 13A, and shows the sealing layer 107 that is additionally rendered over the arrangement shown in FIG. 13A, and the printed wiring board 218 of the wireless device connected to the external contacts 102A and 102B. FIG. 13B thus shows the arrangement of a wireless device 200 according to this embodiment of the invention.

The inductor 214 is formed by the conductor layer 103A3 in this embodiment in the same way as in the tenth embodiment, but as shown in FIG. 13A the capacitor 204P connected to the internal circuit 105 is rendered by part of the inductor 214 and part of the conductor layer 110B1 in the top conductor plate layer 110B. The top conductor plate layer 110B in the tenth embodiment is segmented into a plurality of, such as two conductor layers 110B1 and 110B2. An area of the conductor layer 110B2 is lager than that of the conductor layer 11B1. Each of the conductor layers is also called a conductive film. The conductor layer 110B1 is separated by a slit 11Q from the conductor layer 110B2. As shown in FIG. 13B, the capacitor 204P is formed by a part of the inductor 214 and the conductor layer 110B1 with the dielectric layer 106Q therebetween. The conductor layer 110B1, the conductor layer 103A3 except for the inductor 214, and the pad 104 are connected together, and are connected to the semiconductor substrate 101 through the dielectric layer 106Q and the dielectric layer 106P.

If a capacitor 204Q is connected to the wiring layer of the inductor 214 as shown in FIG. 13C, the desired inductance can be selected.

The internal circuit 105, the aluminum line 206, the pad 104, the inductor 214, the capacitor 204P, the top conductor layer 110A, and the external contact 102A render an active element 20A9. As in the tenth embodiment the top conductor layer 110B is included in the shielding element 20B1. The ground conductor 111, the pad 104, the conductor layer 103B, the top conductor layer 110B1, and the external contacts 102B formed around the perimeter render a shielding element 20B2. The shielding element 20B1 and the shielding element 20B2 are physically separated and electrically isolated from the active element 20A9 by the dielectric layers 106P and 106Q. The active element 20A9 is connected to the printed wiring board 218 by way of intervening external contact 102A, and the shielding elements 20B1 and 20B2 are connected to the printed wiring board 218 and to ground through external contact 102B.

The capacitor 204P is not limited to the arrangement described above, and can be rendered between the different conductor layers in this embodiment. The capacitance of the capacitor 204P can be freely adjusted by controlling the area of the slit 11Q.

### Embodiment 14

Primarily the differences between this fourteenth embodiment of the invention and the foregoing eleventh embodiment are described below. Other aspects of the arrangement, operation and effect of this embodiment of the invention are the same as in the eleventh embodiment, and further description thereof is thus omitted.

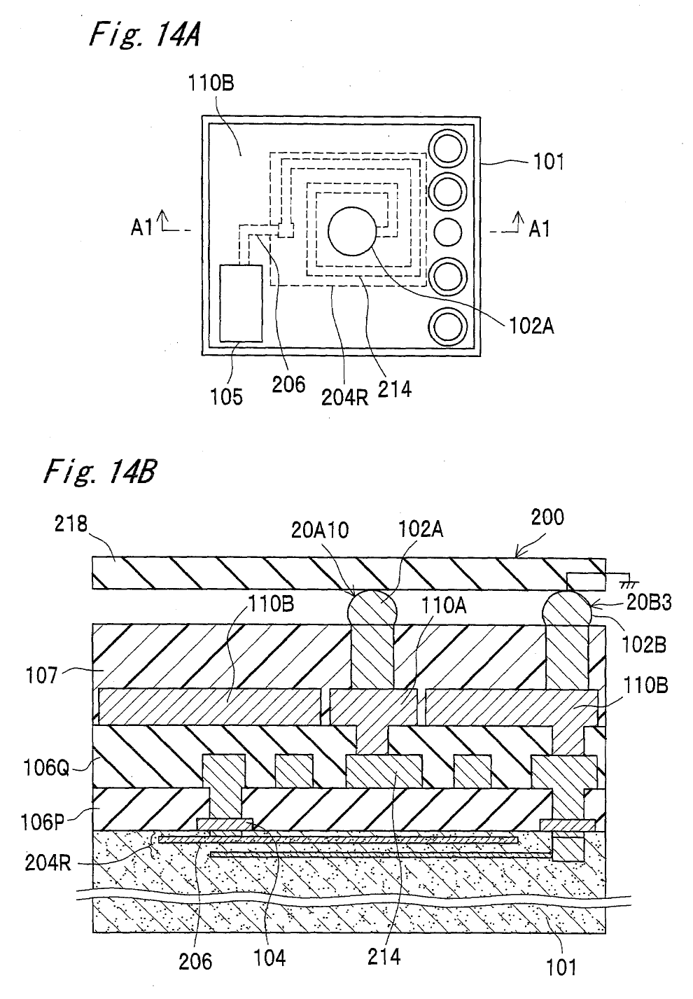

FIG. 14A is a schematic plan view showing some of the elements in a WLCSP arrangement of a semiconductor device 100 according to this eleventh embodiment of the invention.

FIG. 14B is a schematic section view through line A1-A1 in FIG. 14A, and shows the sealing layer 107 that is additionally rendered over the arrangement shown in FIG. 14A, and the printed wiring board 218 of the wireless device connected to the external contacts 102A and 102B. FIG. 14B thus shows the arrangement of a wireless device 200 according to this embodiment of the invention.

The inductor 214 is formed by the conductor layer 103A3 in this embodiment in the same way as in the eleventh embodiment, but as shown in FIG. 14A the capacitor 204R connected to the internal circuit 105 is rendered over the entire area below the inductor 214. This capacitor 204R includes a top electrode and a bottom electrode with the top connected to the aluminum line 206 and the bottom electrode connected to the shielding element 20B3. The inductor 214 is disposed between the top conductor layer 110B and the bottom electrode of the capacitor 204R. The top conductor layer 110B and the bottom electrode of the capacitor 204R are electrically connected to each other and go to ground.

The internal circuit 105, the aluminum line 206, the top electrode of the capacitor 204R, the pad 104, the inductor 214, the top conductor layer 110A, and the external contact 102A render an active element 20A10. The ground conductor 111, the bottom electrode of the capacitor 204R, the pad 104, the conductor layer 103B, the top conductor layer 110B, and the external contacts 102B formed around the perimeter render a shielding element 20B3. The shielding element 20B3 is physically separated and electrically isolated from the active element 20A10 by the dielectric layers 106P and 106Q. The active element 20A10 is connected to the printed wiring board 218 by way of intervening external contact 102A, and the shielding element 20B3 are connected to the printed wiring board 218 and to ground through external contact 102B.

This arrangement reduces the effect of noise from the semiconductor substrate 101 and the printed wiring board 218 on the inductor 214.

### Embodiment 15

Primarily the differences between this fifteenth embodiment of the invention and the foregoing twelfth and fourteenth embodiments are described below. Other aspects of the arrangement, operation and effect of this embodiment of the invention are the same as in the twelfth and fourteenth embodiments, and further description thereof is thus omitted.

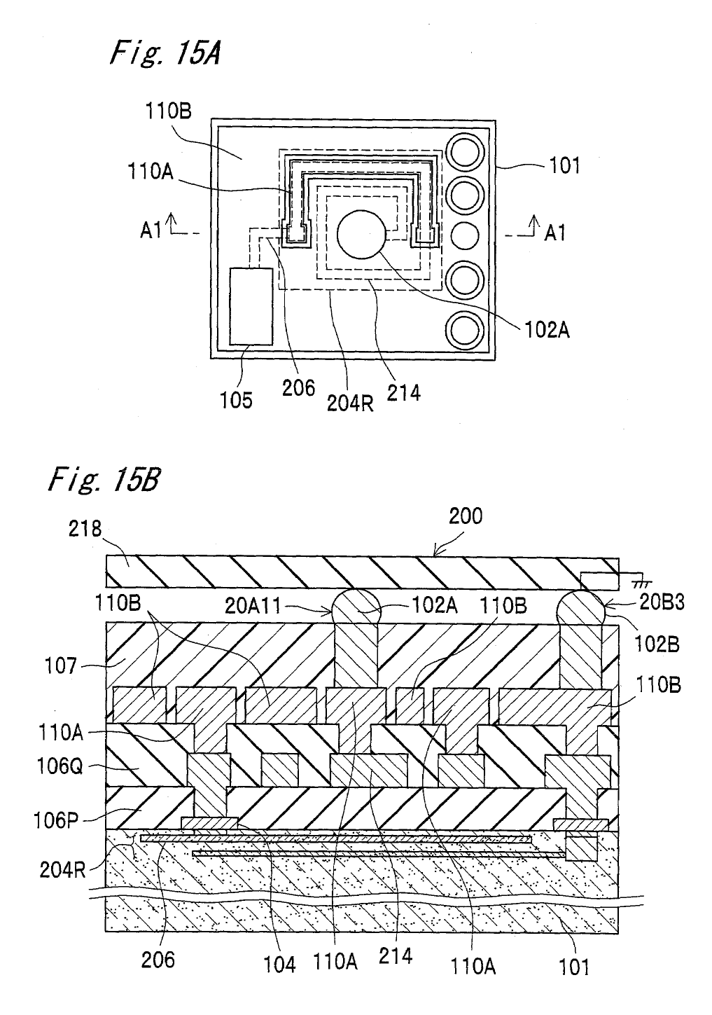

FIG. 15A is a schematic plan view showing some of the elements in a WLCSP arrangement of a semiconductor device 100 according to this eleventh embodiment of the invention.

FIG. 15B is a schematic section view through line A1-A1 in FIG. 15A, and shows the sealing layer 107 that is additionally rendered over the arrangement shown in FIG. 15A, and the printed wiring board 218 of the wireless device connected to the external contacts 102A and 102B. FIG. 15B thus shows the arrangement of a wireless device 200 according to this embodiment of the invention.

The shape of the inductor rendered by the conductor layer 103A3 in this embodiment is the same as in the twelfth embodiment, but the capacitor 204R connected to the internal circuit 105 as shown in FIG. 15A is disposed below the entire area of the inductor 214 as described in the fourteenth embodiment.

The internal circuit 105, the aluminum line 206, the top electrode of the capacitor 204R, the pad 104, the compound inductor 214A, the top conductor layer 110A, and the external contact 102A render an active element 20A11. The ground conductor 111, the bottom electrode of the capacitor 204R, the pad 104, the conductor layer 103B, the top conductor layer 110B, and the external contacts 102B formed around the perimeter render a shielding element 20B3. The shielding element 20B3 is physically separated and electrically isolated from the active element 20A11 by the dielectric layers 106P and 106Q. The active element 20A11 is connected to the printed wiring board 218 by way of intervening external contact 102A, and the shielding element 20B3 are connected to the printed wiring board 218 and to ground through external contact 102B.

This embodiment of the invention affords the same effects as the twelfth and the fourteenth embodiments of the invention.

### Embodiment 16

Primarily the differences between this sixteenth embodiment of the invention and the foregoing sixth to ninth embodiments are described below. Other aspects of the arrangement, operation and effect of this embodiment of the invention are the same as in the sixth to ninth embodiments, and further description thereof is thus omitted.

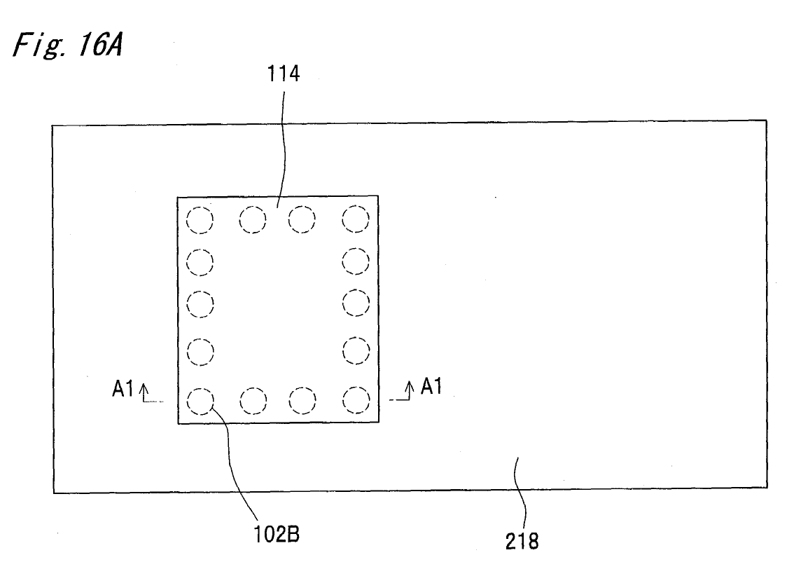

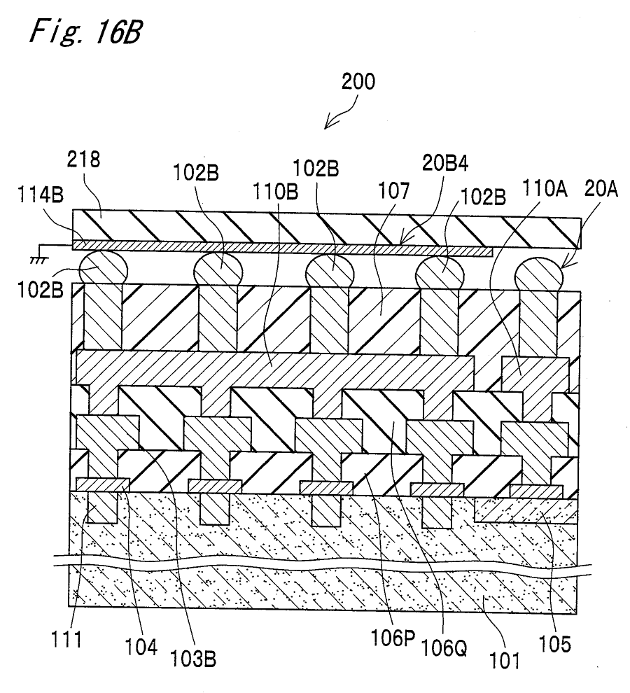

FIG. 16A is a schematic plan view showing some of the elements in a WLCSP arrangement of a semiconductor device 100 according to this eleventh embodiment of the invention.

FIG. 16B is a schematic section view through line A1-A1 in FIG. 16A, and shows the sealing layer 107 that is additionally rendered over the arrangement shown in FIG. 16A, and the printed wiring board 218 of the wireless device connected to the external contacts 102A and 102B. FIG. 16B thus shows the arrangement of a wireless device 200 according to this embodiment of the invention.

This sixteenth embodiment of the invention additionally disposes a conductive layer 114 to the printed wiring board 218. This conductive layer 114 is at least larger in area than the top conductor plate layer 110B in the sixth to ninth embodiments, goes to ground, and is connected to the external contacts 102B.

The internal circuit 105 in this embodiment of the invention renders an active element 20A4. The ground conductor 111, the pad 104, the conductor layer 103B, the top conductor layer 110B, and the external contacts 102B formed around the perimeter render a shielding element 20B4. The wireless device includes the semiconductor substrate 101, the dielectric layers 106P and 106Q, the active element 20A4, the shielding element 20B4, and the printed wiring board 218. The shielding element 20B4 is physically separated and electrically isolated from the active element 20A4 by the dielectric layers 106P and 106Q.

By shielding the layers below the top conductor plate layer 110B and mounting the semiconductor device of the sixth to ninth embodiments independently on the printed wiring board 218, this sixteenth embodiment of the invention reduces interference from other circuit blocks.

### Embodiment 17

Primarily the differences between this seventeenth embodiment of the invention and the foregoing seventh to ninth, tenth, and eleventh embodiments are described below. Other aspects of the arrangement, operation and effect of this embodiment of the invention are the same as in the seventh to ninth, tenth, and eleventh embodiments, and further description thereof is thus omitted.

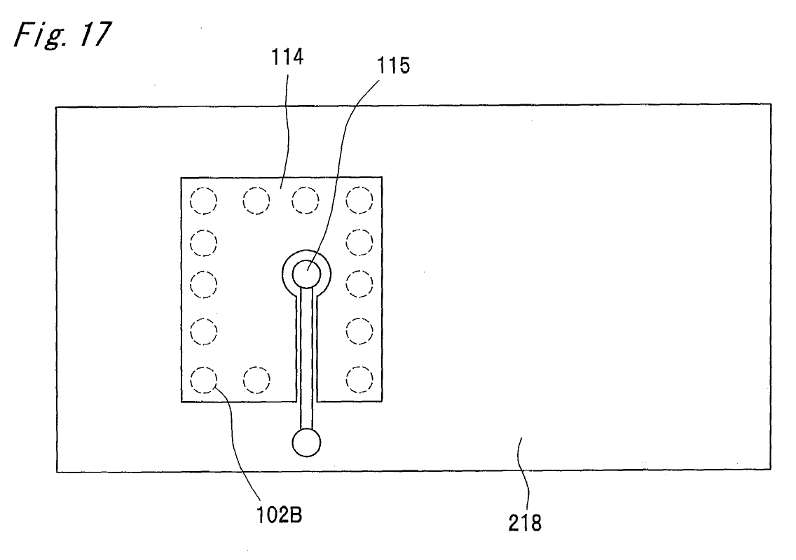

As shown in FIG. 17 the wireless device 200 according to this seventeenth embodiment of the invention removes a part of the conductive layer 114 rendered on the printed wiring board 218 in the sixteenth embodiment, and has a conductive layer 115 isolated from the conductive layer 114. The semiconductor device 100 according to the seventh to ninth, tenth, and eleventh embodiments have a conductor layer 110A in the void formed in part of the top conductor plate layer 110B, and the conductor layer 110A is isolated from and in substantially the same layer as the top conductor plate layer 110B. The external contact 102A disposed on top of this conductor layer 110A is connected to the conductive layer 115 in this embodiment of the invention.

The internal circuit 105, the pad 104, the conductor layer 103A5, the top conductor layer 110A, the external contact 102A, and the conductive layer 115 render an active element 20A5. The ground conductor 111, the pad 104, the conductor layer 103B, the top conductor layer 110B, the external contacts 102B formed around the perimeter, and the conductive layer 114 render a shielding element 20B4. The wireless device includes the semiconductor substrate 101, the dielectric layers 106P and 106Q, the active element 20A5, the shielding element 20B4, and the printed wiring board 218. The shielding element 20B4 is physically separated and electrically isolated from the active element 20A5 by the dielectric layers 106P and 106Q.

By shielding the internal circuit 105 below the top conductor plate layer 110B of the semiconductor device 100 and mounting the external contact 102A of the conductor layer 110A that is isolated from the conductor layer 110B independently on the printed wiring board 218 in the wireless devices according to the seventh to ninth, tenth, and eleventh embodiments of the invention, this seventeenth embodiment of the invention reduces interference from other circuit blocks.

### Embodiment 18

Primarily the differences between this eighteenth embodiment of the invention and the foregoing seventeenth embodiment are described below. Other aspects of the arrangement, operation and effect of this embodiment of the invention are the same as in the seventeenth embodiment, and further description thereof is thus omitted.

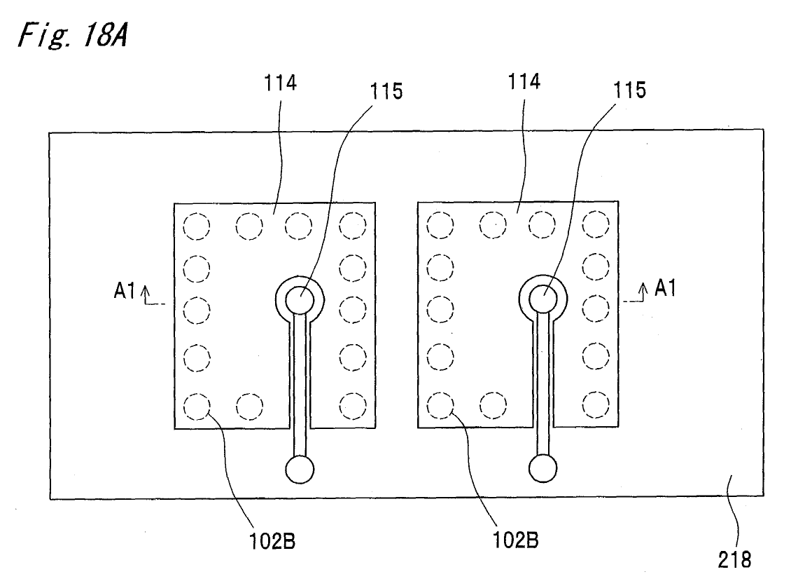

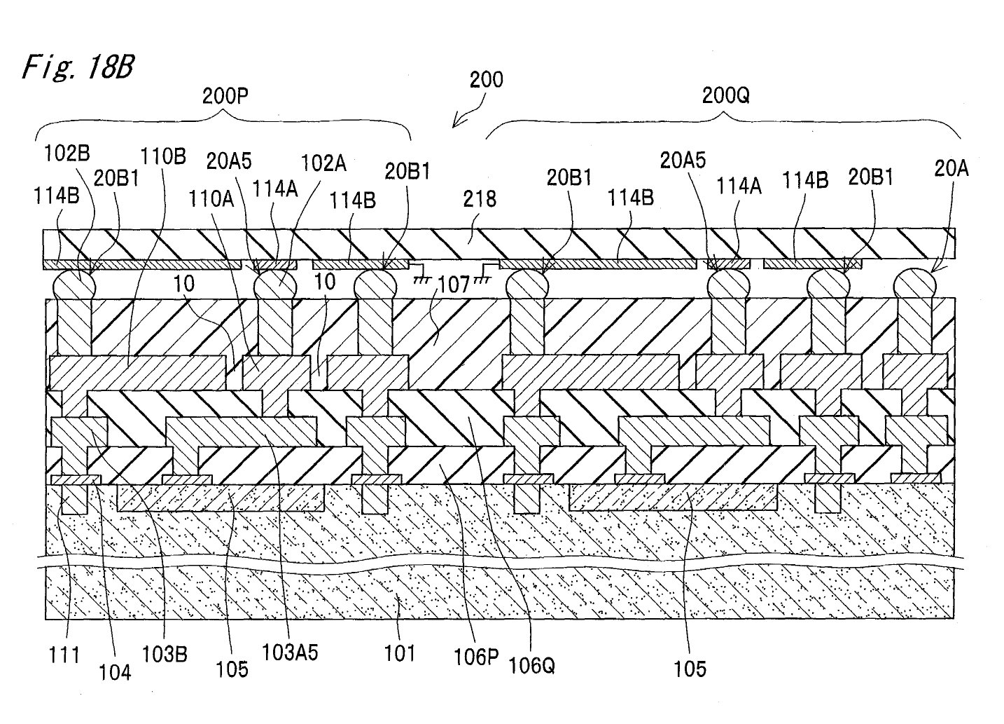

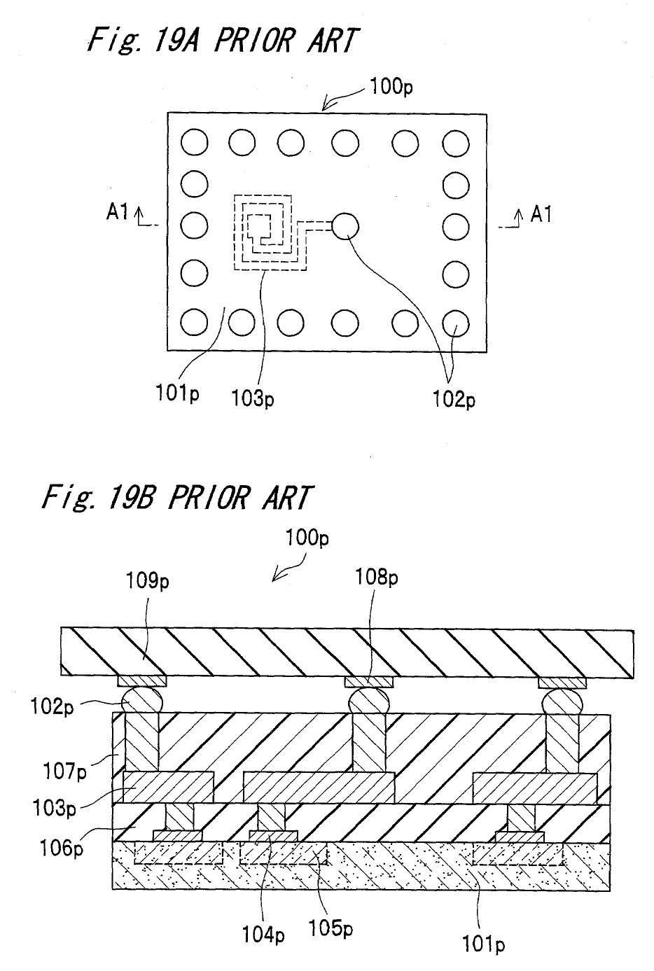

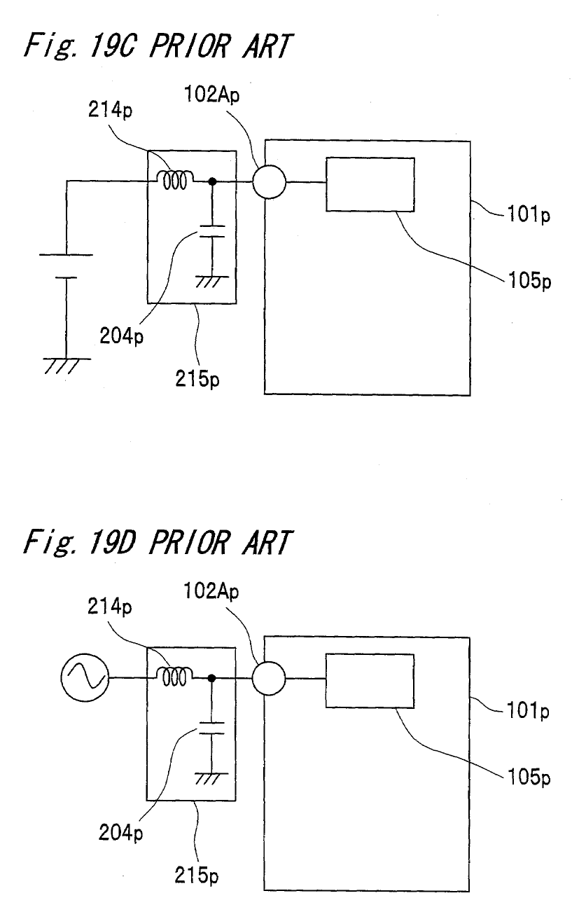

As shown in FIG. 18A and FIG. 18B, the wireless device 200 according to this eighteenth embodiment has wireless devices 200P and 200Q that are identical to the wireless device 200 of the seventeenth embodiment.

The internal circuit 105 contained in the wireless devices 200P and 200Q are electrostatically and electromagnetically shielded in this eighteenth embodiment, and mutual interference is thus reduced.

For example, if a internal circuit 105 for a transmission unit and a reception unit are contained on the semiconductor substrate 101 for a wireless device and operated simultaneously, the output transmission signal can sneak through the inside of the semiconductor substrate 101 or around the printed wiring board 218 to the reception unit and degrade the reception characteristics. This problem can be resolved by rendering the transmission unit and the reception unit using the arrangement of this eighteenth embodiment of the invention.

It will be obvious to one with ordinary skill in the related art that two, three or more wireless devices 200 according to the foregoing seventeenth embodiment can be arranged and described as in this embodiment of the invention.

As described above the present invention can be used in semiconductor devices that can reduce adverse effects from a wireless circuit board when the semiconductor device is mounted on the wireless circuit board.

Although the present invention has been described in connection with the preferred embodiments thereof with reference to the accompanying drawings, it is to be noted that various changes and modifications will be apparent to those skilled in the art. Such changes and modifications are to be understood as included within the scope of the present invention as defined by the appended claims, unless they depart therefrom.

What is claimed is:

1. A semiconductor device comprising:
a semiconductor substrate;
a shielding element formed by a conductor on a top side of said semiconductor substrate;
an active element formed by a conductor and a semiconductor on the top side of said semiconductor substrate;
a dielectric layer formed between said shielding element and said active element to electrically isolate said shielding element and said active element;
wherein said shielding element includes
a first conductor layer formed as a flat plate, and
a first external contact that is formed on the top side of said first conductor layer and is connected to said first conductor layer; and
said active element includes a second conductor layer that is formed between said semiconductor substrate and said first conductor layer, and is connected to said semiconductor substrate.

2. The semiconductor device described in claim 1, wherein said active element comprises:
a second external contact formed on the top side of said second conductor layer; and
a third conductor layer formed between said second conductor layer and said second external contact in substantially the same layer as said first conductor layer, and connected to said second conductor layer and said second external contact.

3. The semiconductor device described in claim 1, wherein said second conductor layer includes an inductor.

4. The semiconductor device described in claim 1, wherein said active element includes an internal circuit formed on said semiconductor substrate.

5. The semiconductor device described in claim 4, wherein said second conductor layer is connected to said internal circuit.

6. The semiconductor device described in claim 5, wherein said active element comprises:
a second external contact formed on the top side of said second conductor layer; and
a third conductor layer formed between said second conductor layer and said second external contact in substantially the same layer as said first conductor layer, and connected to said second conductor layer and said second external contact.

7. The semiconductor device described in claim 6, wherein said second conductor layer includes an inductor.

8. The semiconductor device described in claim 7, wherein said inductor is formed in a spiral around said second external contact.

9. The semiconductor device described in claim 7, wherein said third conductor layer is formed directly above and parallel to at least a part of said inductor, and is substantially the same width as said inductor.

10. The semiconductor device described in claim 9, wherein said third conductor layer is divided into at least two parts.

11. The semiconductor device described in claim 5, wherein said active element includes a capacitor having one end connected to the node between said second conductor layer and said internal circuit.

12. The semiconductor device described in claim 11, wherein the other end of said capacitor is connected to said semiconductor substrate.

13. The semiconductor device described in claim 11, wherein the other end of said capacitor is connected to said shielding element.

14. The semiconductor device described in claim 13, wherein said first conductor layer is segmented into a first conductive film with a relatively large area and a second conductive film with a relatively small area;
said shielding element includes
a first shielding element including said first conductive film, and
a second shielding element including said second conductive film; and
the other end of said capacitor is connected to said second conductive film.

15. The semiconductor device described in claim 13, wherein said shielding element includes a ground conductor that is formed on said semiconductor substrate and connected to said semiconductor substrate; and
the other end of said capacitor is connected to said ground conductor.

16. The semiconductor device described in claim 11, wherein said capacitor is formed using a metal-insulate-metal structure.

17. The semiconductor device described in claim 1, wherein said shielding element includes a ground conductor that is formed on said semiconductor substrate and connected to said semiconductor substrate; and
said first conductor layer is connected to said ground conductor.

18. The semiconductor device described in claim 1, wherein said first external contact is grounded.

19. The semiconductor device described in claim 1, wherein said first conductor layer includes an opening.

20. The semiconductor device described in claim 1, wherein said first external contact is formed near the perimeter of said first conductor layer.

21. The semiconductor device described in claim 1, comprising:
N sets (where N is an integer greater than or equal to 2) of shielding elements, active elements, and dielectric layers; and
one semiconductor substrate.

22. A wireless device comprising:
a semiconductor device including a semiconductor substrate,
a shielding element formed by a conductor on a top side of said semiconductor substrate;
an active element formed by a conductor and a semiconductor on the top side of said semiconductor substrate;
a dielectric layer formed between said shielding element and said active element to electrically isolate said shielding element and said active element;
wherein said shielding element includes
a first conductor layer formed as a flat plate, and
a first external contact that is formed on the top side of said first conductor layer and is connected to said first conductor layer; and
said active element includes a second conductor layer that is formed between said semiconductor substrate and said first conductor layer, and is connected to said semiconductor substrate;
a third conductor layer that is formed in an area greater than said first conductor layer on the top side of said first external contact, and is connected to said first external contact; and
a wiring board to which said third conductor layer is attached.

23. The wireless device described in claim 22, wherein:
said active element includes a second external contact formed on the top side of said second conductor layer;
said third conductor layer is segmented into a first conductive film with a relatively large area and a second conductive film with a relatively small area that is electrically isolated from said first conductive film;
said first conductive film is connected to said first external contact; and
said second conductive film is connected to second external contact.

24. The wireless device described in claim 22, comprising:
N sets (where N is an integer greater than or equal to 2) of said semiconductor devices and said third conductor layers; and
one semiconductor substrate.
